(19) United States
(12) Patent Application Publication
(10) Pub. No.: US 2025/0359219 A1
(43) Pub. Date: Nov. 20, 2025

(54) SEMICONDUCTOR STRUCTURE AND METHOD FOR FORMING THE SAME

(71) Applicant: Taiwan Semiconductor Manufacturing Company, Ltd., Hsin-Chu (TW)

(72) Inventors: Kuan-Ting Pan, Taipei City (TW); Yi-Ruei Jhan, Keelung City (TW); Kuo-Cheng Chiang, Hsinchu County (TW); Chih-Hao Wang, Hsinchu (TW)

(21) Appl. No.: 19/286,805

(22) Filed: Jul. 31, 2025

Related U.S. Application Data
(63) Continuation of application No. 18/764,684, filed on Jul. 5, 2024.
(60) Provisional application No. 63/636,424, filed on Apr. 19, 2024.

(51) Int. Cl. H10D 62/10; H10D 30/01; H10D 30/43; H10D 30/67; H10D 64/01

(52) U.S. Cl. CPC H10D 62/121; H10D 30/6735; H10D 64/017; H10D 64/018; H10D 30/014; H10D 30/43; H10D 30/6757

(57) ABSTRACT

A semiconductor structure is provided. The semiconductor structure includes a first plurality of nanostructures between a first source/drain feature and a second source/drain feature, a first gate segment surrounding the first plurality of nanostructures, and a wall structure abutting the first gate segment. A first nanostructure in the first plurality of nanostructures includes a bulk portion and a protrusion, and the protrusion protrudes from a first sidewall of the bulk portion toward the wall structure.

### PRIORITY CLAIM

This application is a Continuation of U.S. patent application Ser. No. 18/764,684, filed Jul. 5, 2024, which further claims the benefit of U.S. Provisional Application No. 63/636,424, filed on Apr. 19, 2024, and entitled “Semiconductor device and Method for forming the same,” the entire disclosures of which are incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. GAA devices provide a channel in a silicon nanowire/nanosheet. However, integration of fabrication of the GAA features around the nanowire/nanosheet can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIG. 3A is a cross-sectional view illustrating the formation of a semiconductor structure at one of the intermediate stages, in accordance with some embodiments.

FIG. 3B is a cross-sectional view illustrating the formation of a semiconductor structure at one of the intermediate stages, in accordance with some embodiments.

FIG. 3C is a perspective view illustrating the formation of a semiconductor structure at one of the intermediate stages, in accordance with some embodiments.

FIGS. 3D-1 and 3D-2 are cross-sectional views illustrating the formation of a semiconductor structure at one of the intermediate stages, in accordance with some embodiments.

FIGS. 3E-1 and 3E-2 are cross-sectional views illustrating the formation of a semiconductor structure at one of the intermediate stages, in accordance with some embodiments.

FIGS. 3F-1 and 3F-2 are cross-sectional views illustrating the formation of a semiconductor structure at one of the intermediate stages, in accordance with some embodiments.

FIGS. 3G-1, 3G-2 and 3G-3 are schematic views illustrating the formation of a semiconductor structure at one of the intermediate stages, in accordance with some embodiments.

FIGS. 3H-1, 3H-2 and 3H-3 are schematic views illustrating the formation of a semiconductor structure at one of the intermediate stages, in accordance with some embodiments.

FIGS. 3I-1 and 3I-2 are schematic views illustrating the formation of a semiconductor structure at one of the intermediate stages, in accordance with some embodiments.

FIG. 3J is a cross-sectional view illustrating the formation of a semiconductor structure at one of the intermediate stages, in accordance with some embodiments.

FIG. 3K is a cross-sectional view illustrating the formation of a semiconductor structure at one of the intermediate stages, in accordance with some embodiments.

FIG. 3L is a cross-sectional view illustrating the formation of a semiconductor structure at one of the intermediate stages, in accordance with some embodiments.

FIGS. 3M-1 and 3M-2 are cross-sectional views illustrating the formation of a semiconductor structure at one of the intermediate stages, in accordance with some embodiments.

FIG. 3N-1 is a cross-sectional view illustrating the formation of a semiconductor structure at one of the intermediate stages, in accordance with some embodiments.

FIG. 3O is a cross-sectional view illustrating the formation of a semiconductor structure at one of the intermediate stages, in accordance with some embodiments.

FIGS. 3P-1 and 3P-2 are cross-sectional views illustrating the formation of a semiconductor structure at one of the intermediate stages, in accordance with some embodiments.

FIGS. 3Q-1, 3Q-2, 3Q-3 and 3Q-5 are schematic views illustrating the formation of a semiconductor structure at one of the intermediate stages, in accordance with some embodiments.

FIG. 3N-2 is an enlarged view of the semiconductor structure of FIG. 3N-1 to illustrate more detail of a semiconductor feature and neighboring components, in accordance with some embodiments.

FIG. 3Q-4 is an enlarged view of the semiconductor structure of FIG. 3Q-1 to illustrate more detail of a semiconductor feature and neighboring components, in accordance with some embodiments.

FIGS. 4A and 4B are a modification of the semiconductor structure of FIGS. 3N-2 and 3Q-4 respectively, in accordance with some embodiments.

FIG. 5 is a modification of the semiconductor structure of FIG. 3Q-4, in accordance with some embodiments.

FIGS. 6A-6D are cross-sectional views illustrating the formation of a semiconductor structure at various intermediate stages, in accordance with some embodiments.

FIGS. 7A, 7B-1 and 7B-2 are schematic views illustrating the formation of a semiconductor structure at various intermediate stages, in accordance with some embodiments.

FIGS. 8A, 8B-1 and 8B-2 are schematic views illustrating the formation of a semiconductor structure at various intermediate stages, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The semiconductor structure includes a wall structure, which is formed self-aligned at the location of the gate structures between the active region. The formation of the wall structure may facilitate achieving a minimum space between an active region and a gate-cut feature. In addition, the semiconductor structure further includes the semiconductor features grown on the sidewalls of the channel layers of an active region facing the wall structure. The semiconductor features and channel layers may collectively serve as channel of the resulting transistor. Therefore, the total cell capacitance of the resulting semiconductor device may be reduced, and scaling down the resulting semiconductor device may be achieved, and/or the on-state current of the resulting semiconductor device may increase.

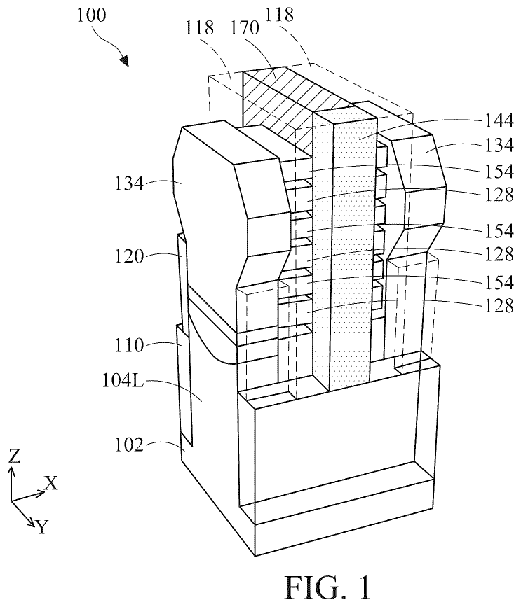

FIG. 1 is a perspective view of a semiconductor structure 100, in accordance with some embodiments. The semiconductor structure 100 includes a lower fin element 104L over a substrate 102, an isolation structure 110 surrounding the lower fin element 104L, and a nanostructure transistor (such as GAA transistors) formed over the lower fin element 104L, in accordance with some embodiments. The nanostructure transistor includes a plurality of nanostructures 154, source/drain features 134 adjoining the nanostructures 154, and a gate stack 170 wrapping each of the nanostructures 154, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate. The Y-axis is transverse (e.g., substantially perpendicular) to the X-axis. The Z-axis is generally oriented along the vertical direction that is perpendicular to the main surface of the substrate (or the X-Y plane).

The nanostructures 154 extend between the source/drain features 134 in the X direction, in accordance with some embodiments. The nanostructures 154 function as the channels of the nanostructure transistors, in accordance with some embodiments. The X direction may also be referred to as the channel-extending direction. The current of the resulting semiconductor device (i.e., nanostructure transistor) flows in the X direction through the channels. It is noted that in the present disclosure, source/drain region(s) or source/drain feature(s) may refer to a source or a drain, individually or collectively dependent upon the context.

The gate stack 170 is formed with a longitudinal axis parallel to the Y direction and extending across the lower fin element 104L and surrounding the nanostructures 154, in accordance with some embodiments. The Y direction may also be referred to as a gate-routing direction, in accordance with some embodiments.

The semiconductor structure 100 further includes gate spacer layers 118 alongside the opposite sidewalls of the gate stack 170, the fin spacer layers 120 alongside the opposite sidewalls of lower portions of the source/drain features 134, and inner spacer layers 128 vertically sandwiched between the nanostructures 154 and laterally between the source/drain features 134 and the gate stack 170, in accordance with some embodiments. The semiconductor structure 100 further includes a wall structure 144 abutting the gate stack 170 and the nanostructures 154 and sandwiched between the gate spacer layers 118, in accordance with some embodiments.

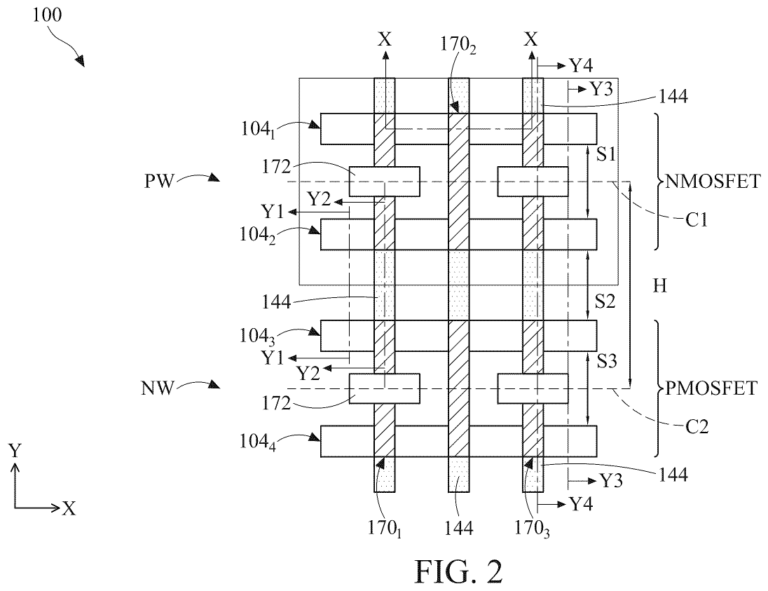

FIG. 2 is a layout of a semiconductor structure 100, in accordance with some embodiments. The semiconductor structure 100 includes active regions 104 (including 104₁₋₄) over a substrate (e.g., substrate 102 shown in FIG. 1), and final gate stacks 170 (including 170₁₋₃) across the active regions 104, in accordance with some embodiments. The active regions 104 extend in the X direction, in accordance with some embodiments. The active regions 104 have longitudinal axes parallel to the X direction, in accordance with some embodiments.

The substrate includes a p-type well PW in which the active regions 104₁ and 104₂ are formed and an n-type well NW in which the active regions 104₃ and 104₄ are formed, in accordance with some embodiments. Each of the active regions 104 includes a lower fin element (e.g., lower fin element 104L shown in FIG. 1) and nanostructures (e.g., nanostructures 154 shown in FIG. 1) formed over the lower fin element, in accordance with some embodiments.

The final gate stacks 170 extend in the Y direction across the lower fin elements and wrap around the nanostructures, in accordance with some embodiments. The final gate stacks 170 have longitudinal axes parallel to the Y direction, in accordance with some embodiments. The final gate stacks 170 are combined with the active regions 104 to form nanostructure transistors, in accordance with some embodiments. The nanostructure transistors are formed at the cross points between the active regions 104 and the final gate stacks 170, in accordance with some embodiments. For example, the nanostructure transistors formed in the p-type well PW are n-channel nanostructure transistors NMOSFET, and the nanostructure transistors formed in the n-type well NW are p-channel nanostructure transistors PMOSFET.

In some embodiments, an area of the substrate may be defined as several cell regions, and several nanostructure transistors are located in each cell region to build a functional circuit. FIG. 2 illustrates the boundaries C1 and C2 of a cell region, in accordance with some embodiments. The boundaries C1 and C2 extend in the X direction. Although not shown, the cell region has boundaries that extend in the Y direction.

The semiconductor structure 100 further includes wall structures 144 and gate-cut structures 172, in accordance with some embodiments. Both the wall structures 144 and the gate-cut structures 172 are configured to divide the gate stack 170, in accordance with some embodiments. In some embodiments, each of the gate-cut structures 172 extends in the X direction and are aligned with the boundary C1 or C2 of the cell region. In some embodiments, each of the wall structures 144 extends in the Y direction, and is formed aligned with the gate stack 170 and within the cell region. In some embodiments, the wall structures 144 are located on the boundary between the n-type well NW and p-type well PW. In some other embodiments, the wall structures 144 may be aligned with the boundaries of a cell region, while the gate-cut structures 172 are located within the cell region.

In some embodiments, the spacing S1 between the active regions 104₁ and 104₂ and the spacing S3 between the active regions 104₃ and 104₄ are in a range from about 30 nm to about 60 nm. In some embodiments, the spacing S2 between the active regions 104₂ and 104₃ is in a range from about 20 nm to about 40 nm. In some embodiments, the spacing S1 and the spacing S3 are greater than the spacing S2. In some other embodiments, the spacing S2 is equal to or greater than the spacing S1 and the spacing S3.

The space between an active region 104 and a gate-cut feature (e.g., the wall structures 144 or gate-cut feature 172) may be referred to as an end-cap dimension. The wall structures 144 may be configured to cut the gate in a manner that minimizes the end-cap dimension. As a result, the total cell capacitance of the resulting semiconductor device may be reduced, and the performance (e.g., speed) of the resulting semiconductor device may be enhanced.

In addition, compared to the formation of the gate-cut structures 172, the formation of the wall structures 144 may be less constrained by the overlay (OVL) and/or critical dimension uniformity (CDU) requirements of a photolithography process, which will be discussed in detail later. Therefore, the formation of the wall structure 144 may facilitate scaling down the spacing S2, and thus continuously scaling down the cell height H of the cell region may be achieved. In some embodiments, the cell height H is reduced by about 25% to about 35%.

FIG. 2 further illustrates reference cross-sections that are used in later figures. Cross-section X-X is in a plane parallel to the longitudinal axis (X direction) of the active regions 104 and through the active region 104₁, in accordance with some embodiments. Cross-section Y1-Y1 is in a plane parallel to the longitudinal axis (Y direction) of the final gate stacks 170 and across the source/drain regions of the active regions 104₂ and 104₃. Cross-section Y2-Y2 is in a plane parallel to the longitudinal axis (Y direction) of the final gate stacks 170 and through the final gate stack 170₁. Cross-section Y3-Y3 is in a plane parallel to the longitudinal axis (Y direction) of the final gate stacks 170 and across the source/drain regions of the active regions 104₁ to 104₄. Cross-section Y4-Y4 is in a plane parallel to the longitudinal axis (Y direction) of the final gate stacks 170 and through the final gate stack 1703.

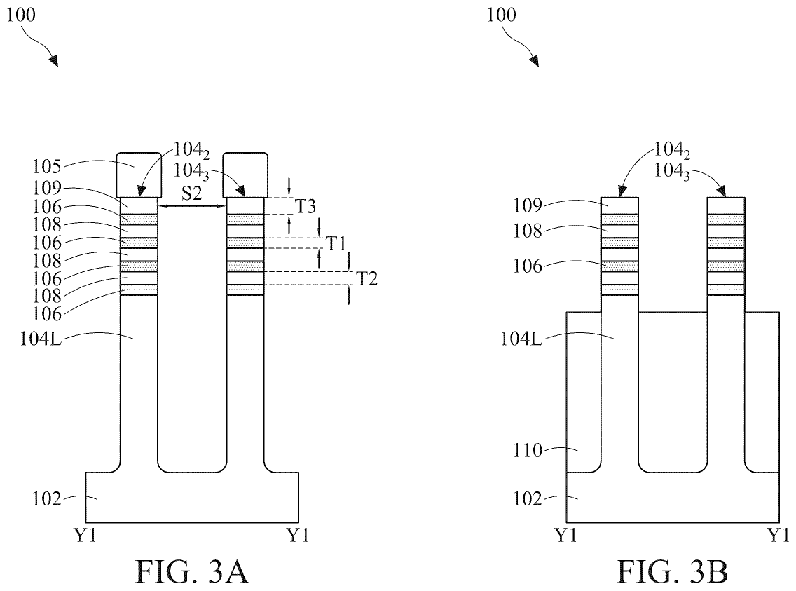

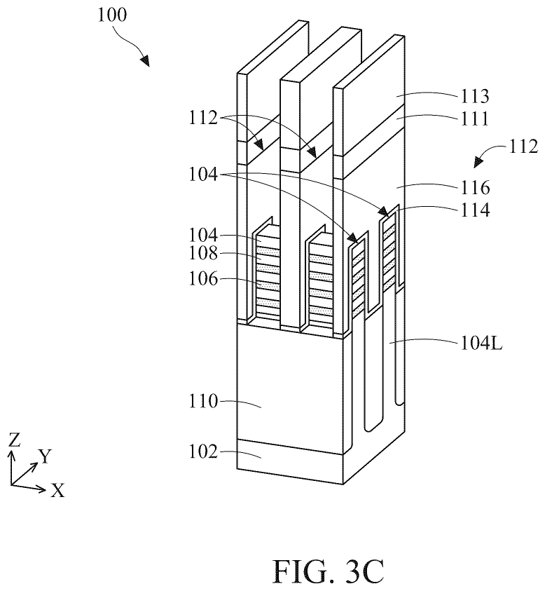

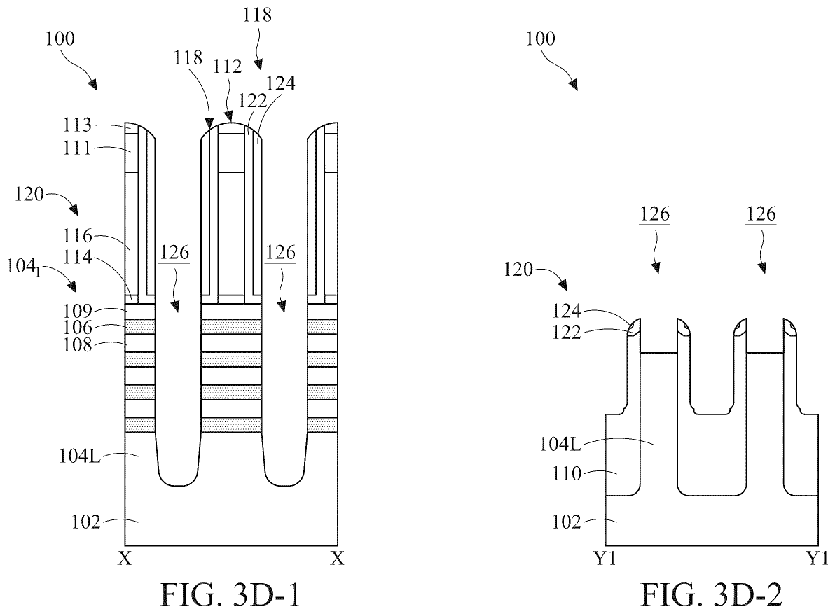

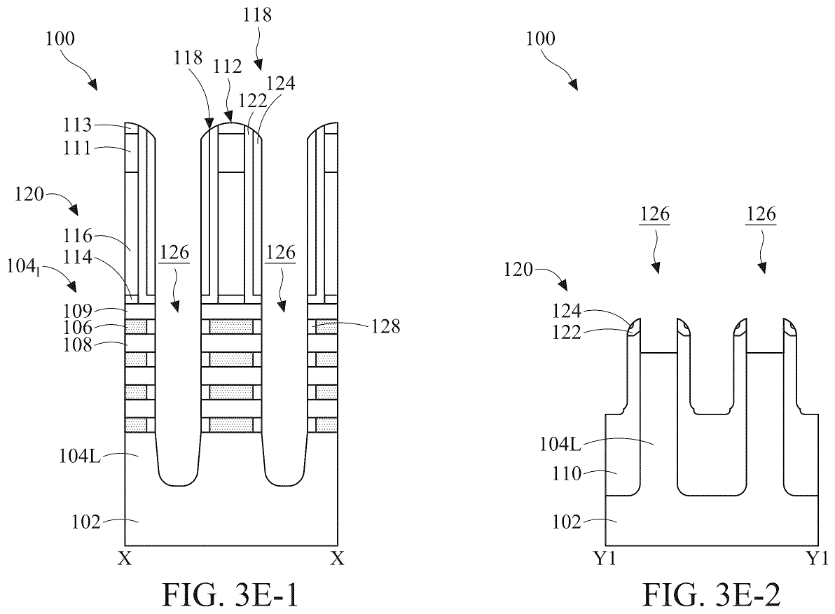

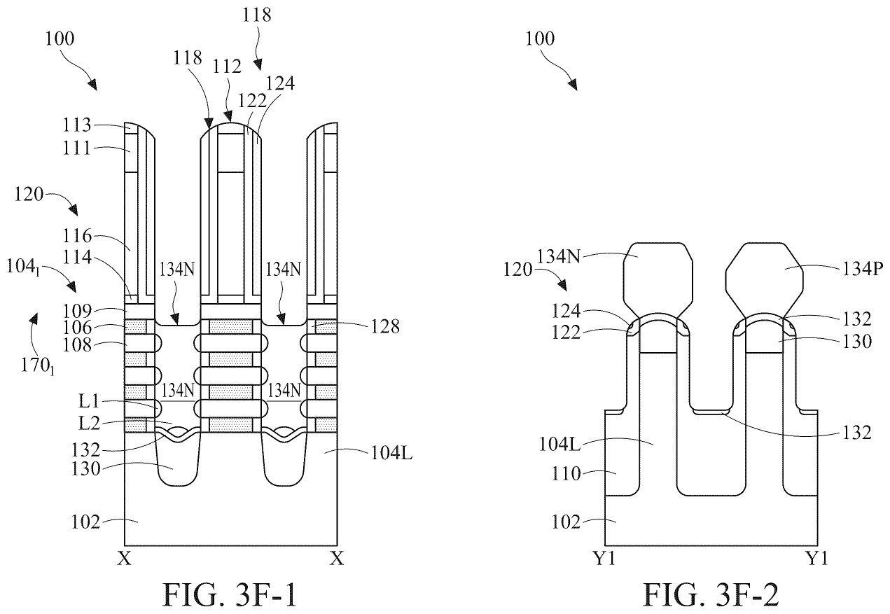

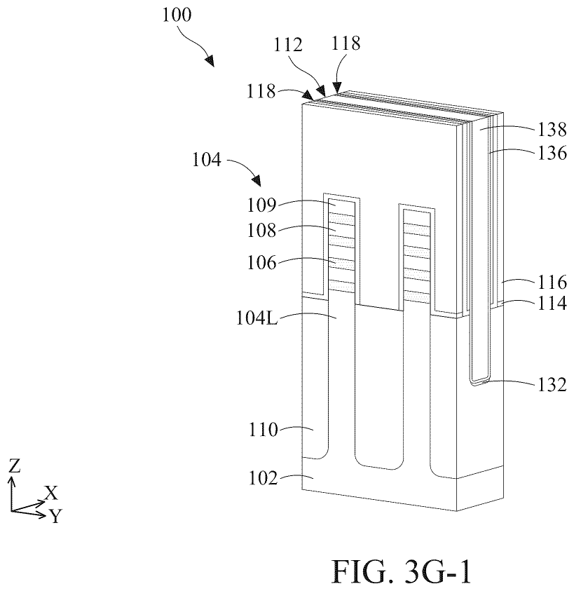

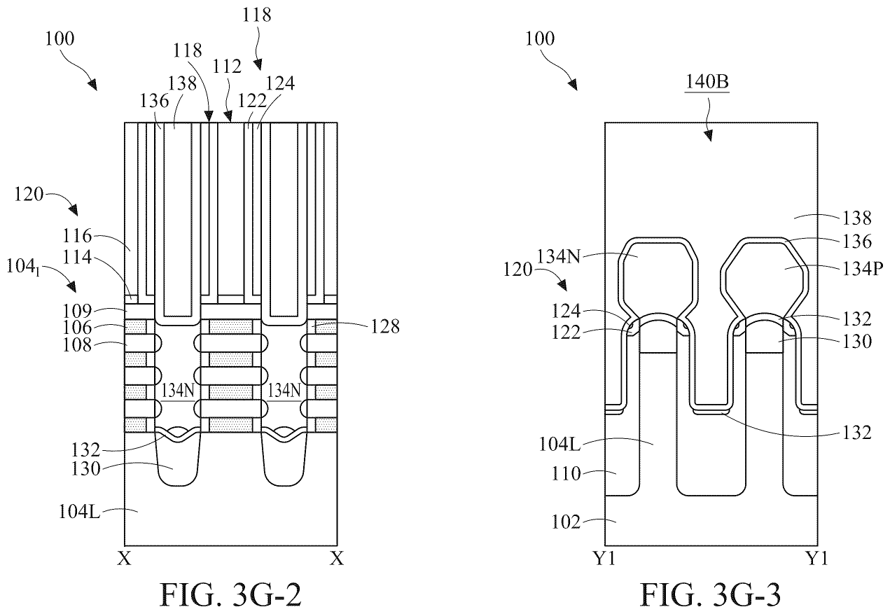

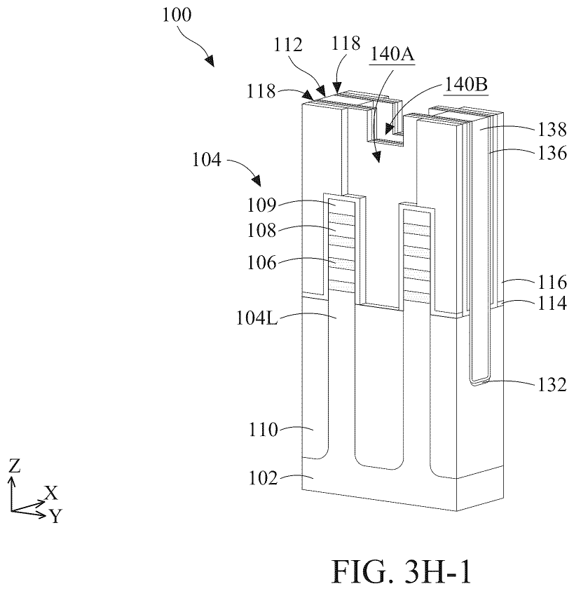

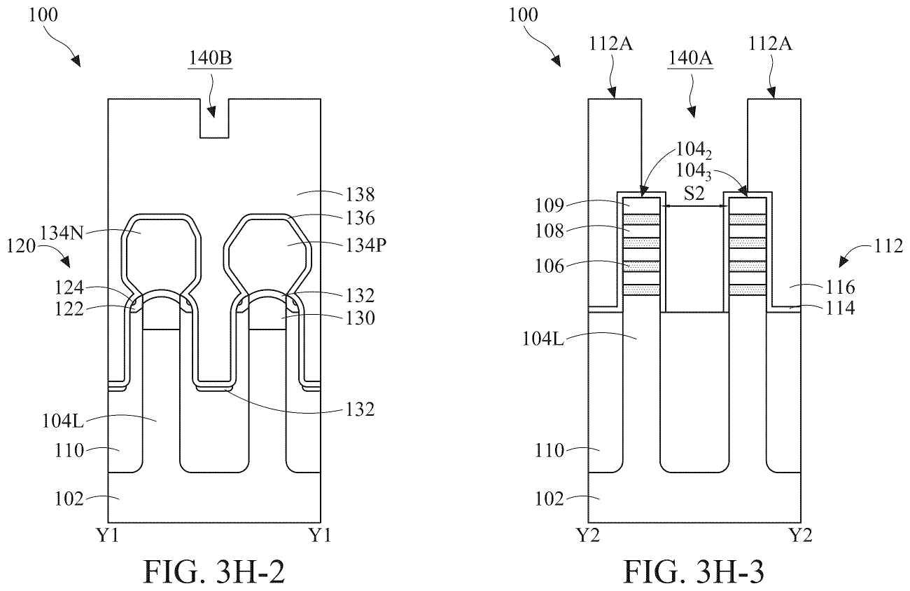

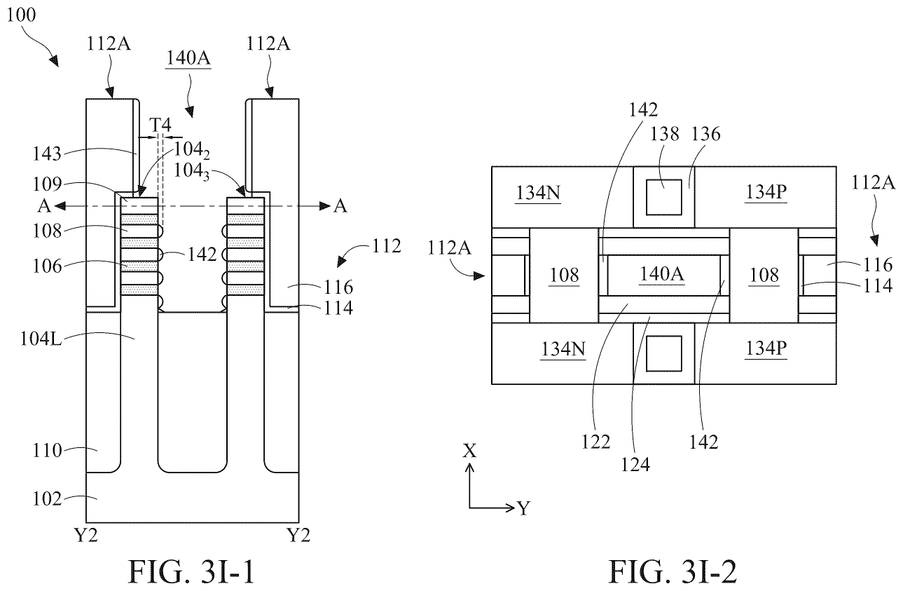

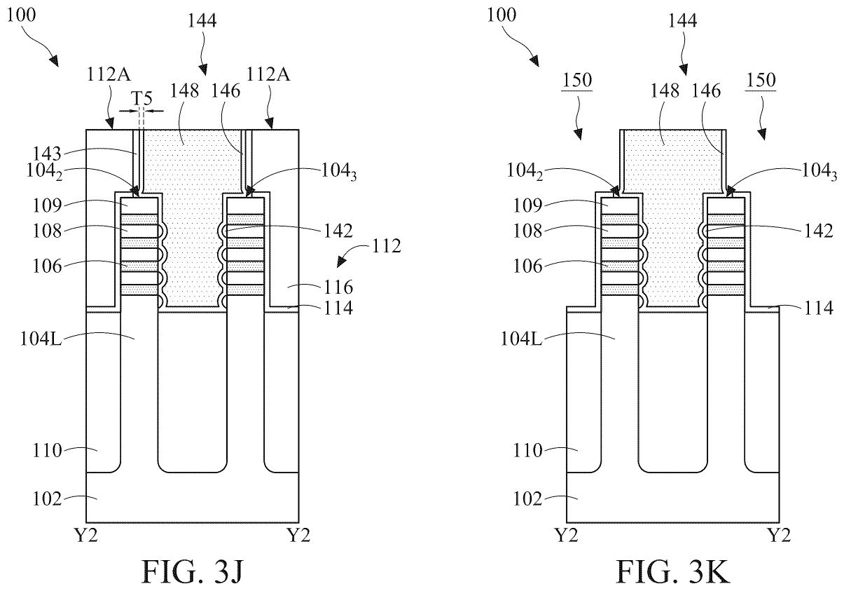

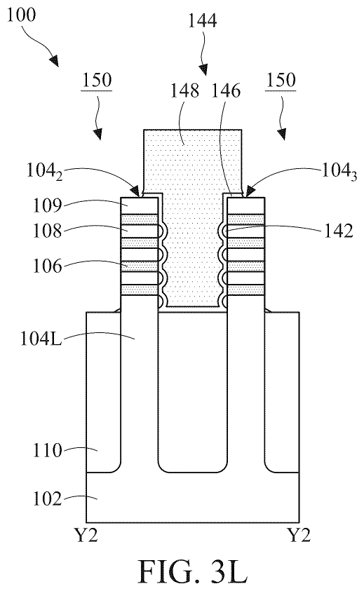

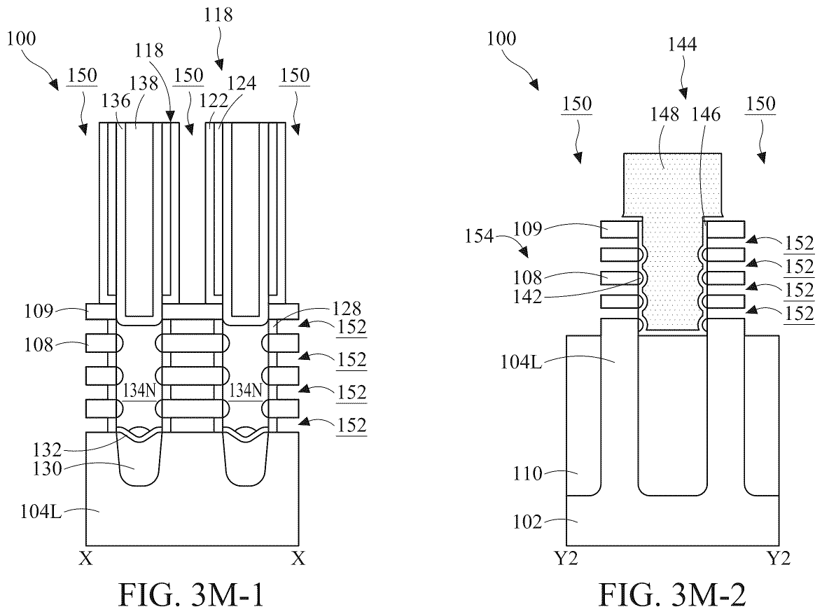

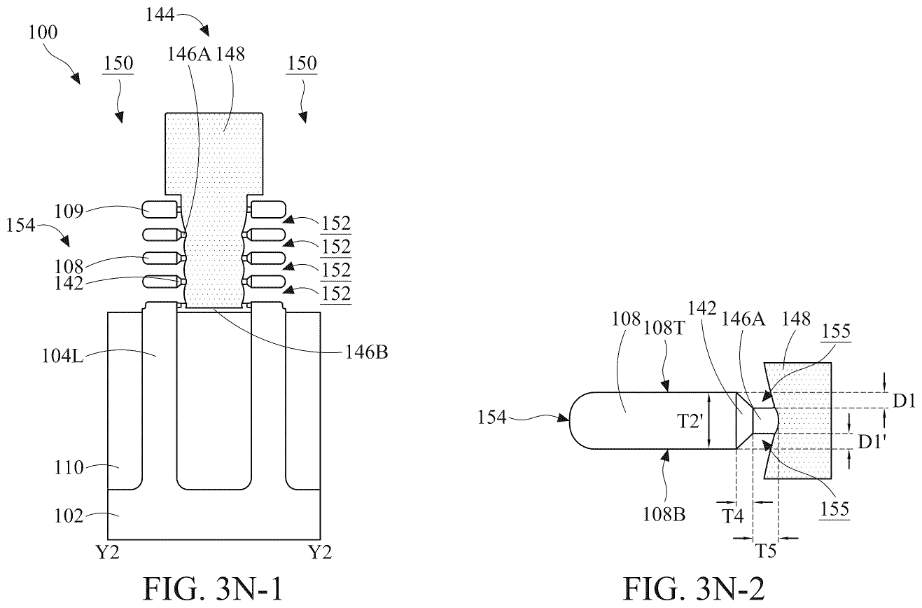

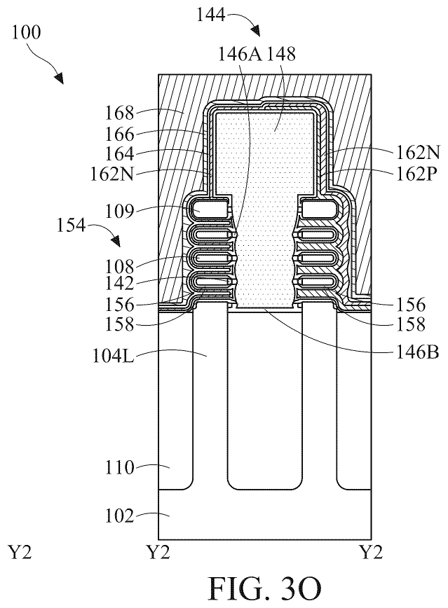

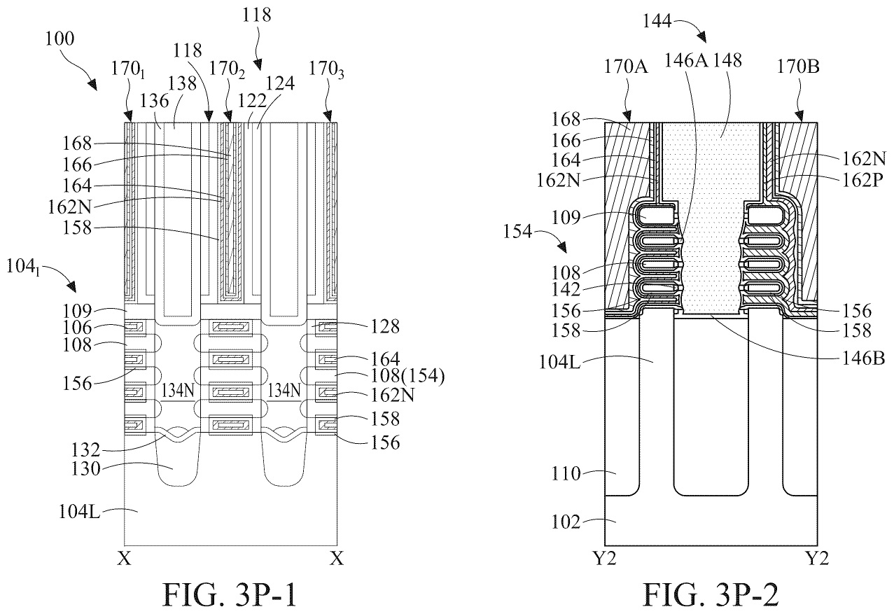

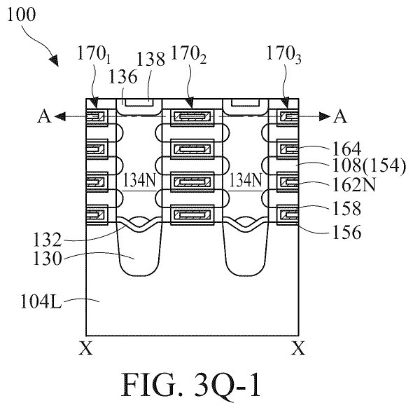

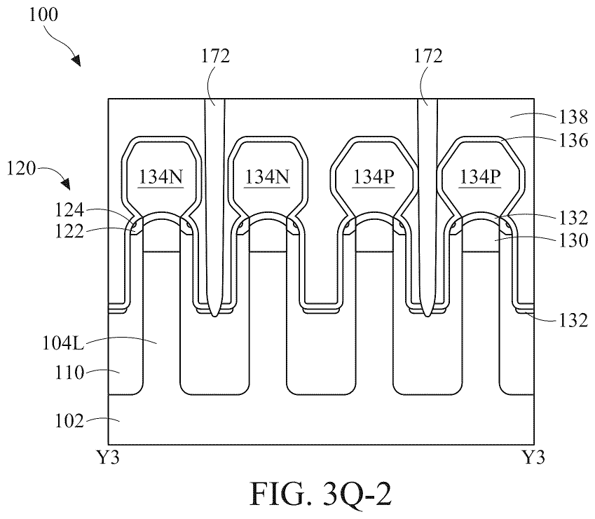

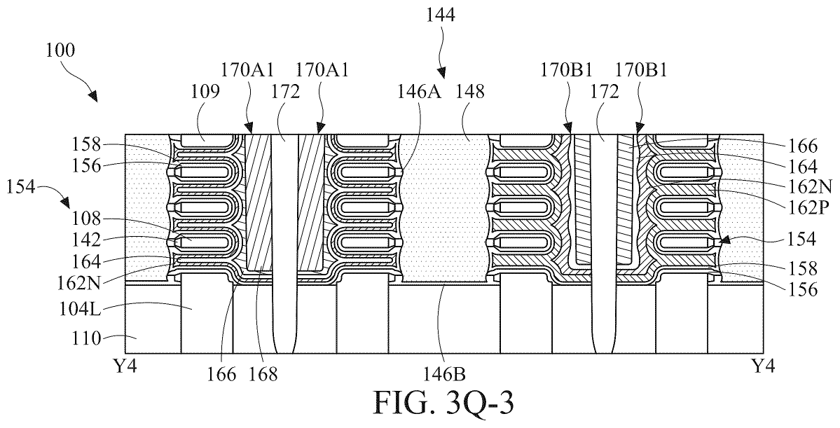

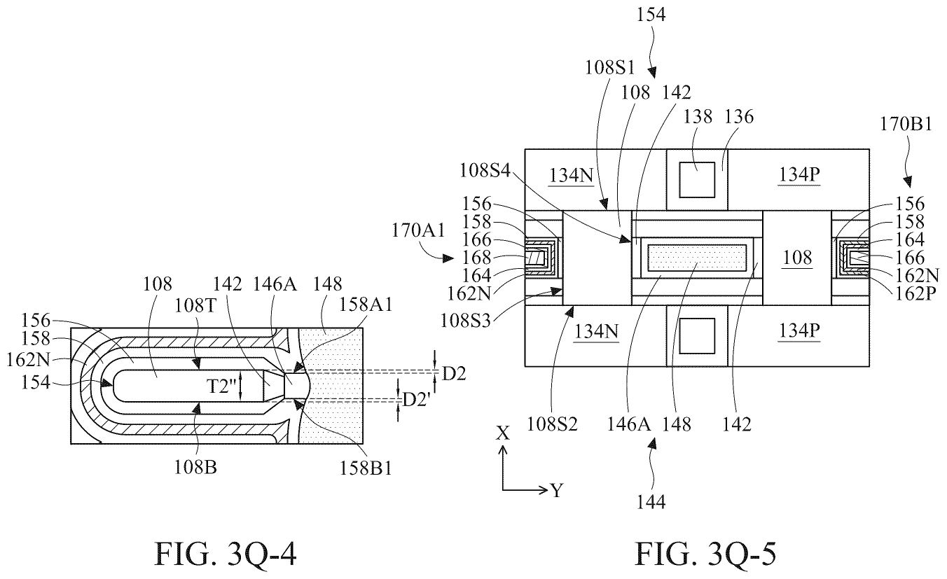

FIGS. 3A through 3Q-5 are schematic views illustrating the formation of the semiconductor structure 100 of FIG. 2 at various intermediate stages, in accordance with some embodiments of the disclosure. FIGS. 3A, 3B, 3D-2, 3E-2, 3F-2, 3G-3 and 3H-2 are cross-sectional views of the semiconductor structure 100 corresponding to line Y1-Y1 of FIG. 2. FIGS. 3C, 3G-1 and 3H-1 are perspective view views of the semiconductor structure 100. FIGS. 3D-1, 3E-1, 3F-1, 3G-2, 3M-1, 3P-1 and 3Q-1 are cross-sectional views of the semiconductor structure 100 corresponding to line X-X of FIG. 2. FIGS. 3H-3, 3I-1, 3J, 3K, 3L, 3M-2, 3N-1, 3O and 3P-2 are cross-sectional views of the semiconductor structure 100 corresponding to line Y2-Y2 of FIG. 2. FIG. 3Q-2 is a cross-sectional view of the semiconductor structure corresponding to line Y3-Y3 of FIG. 2. FIG. 3Q-3 is a cross-sectional view of the semiconductor structure 100 corresponding to line Y4-Y4 of FIG. 2.

FIG. 3A illustrates the semiconductor structure 100 after the formation of active regions 104, in accordance with some embodiments of the disclosure. A semiconductor structure 100 is provided, in accordance with some embodiments. The semiconductor structure 100 includes a substrate 102 and active regions 104 over the substrate 102, as shown in FIG. 3A, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, n-type wells and p-type wells (e.g., NW and PW shown in FIG. 2) are formed in the substrate 102 using ion implantation processes. In some embodiments, the respective concentrations of the dopants in the n-type wells and p-type are in a range from about 10¹⁶/cm⁻³ to about 10¹⁸/cm⁻³. In some embodiments, the ion implantation processes may be performed several times with different dosages and different energy intensities. In some embodiments, the ion implantation process may include anti-punch through (APT) implant.

In some embodiments, the active regions 104 are also referred to as fins or fin structures. Each of the active regions 104 is defined as several channel regions and several source/drain regions, where the channel regions and the source/drain regions are alternately arranged, in accordance with some embodiments. Each of the active regions 104 includes a lower fin element 104L, an upper fin element and a mask layer 109, in accordance with some embodiments. The lower fin element 104L is formed from a portion of the substrate 102 (or the well), in accordance with some embodiments. The upper fin element is formed from an epitaxial stack including alternating first semiconductor layers 106 and second semiconductor layers 108, in accordance with some embodiments.

The formation of the active regions 104 includes forming an epitaxial stack over the substrate 102 using an epitaxial growth process, and forming a dielectric layer for mask layer 109 on the epitaxial stack, in accordance with some embodiments. The epitaxial stack may be formed by depositing a first semiconductor layer 106 on the substrate 102, depositing a second semiconductor layer 108 on the first semiconductor layer 106, and repeating the cycle of depositing the semiconductor layers 106 and 108 several times. The first semiconductor layers 106 and the second semiconductor layers 108 are alternately stacked, in accordance with some embodiments. In some embodiments, the number of the first semiconductor layers 106 is one greater than the number of the second semiconductor layers 108. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shaped and/or sheet shape. Although three second semiconductor layers 108 are shown, the number is not limited to three, and can be two or four, and is less than ten.

The mask layer 109 is made of low-k dielectric material (e.g., with k-value less than 7.9) such as silicon nitride (SiN), silicon oxide (SiO₂), silicon oxynitride (SiON), silicon carbide (SiC), oxygen-doped silicon carbide (SiC:O), silicon carbon nitride (SiCN), oxygen-doped silicon carbonitride (Si(O)CN), or a combination thereof. In some embodiments, the dielectric material is deposited using CVD (such as low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

In some embodiments, the thickness T1 of each of the first semiconductor layers 106 is in a range from about 4 nm to about 14 nm. In some embodiments, the thickness T2 of each of the second semiconductor layers 108 is in a range from about 3 nm to about 9 nm. The thickness of the second semiconductor layers 108 may be greater than, equal to, or less than the first semiconductor layers 106, which may depend on the amount of the gate materials to be filled in spaces where the first semiconductor layers 106 are removed. In some embodiments, the mask layer 109 has a thickness T3 in a range from about 1 nm to about 8 nm.

The formation of the active regions 104 further includes forming a patterned mask layer 105 over the dielectric material using a photolithography process, and etching the dielectric layer, the epitaxial stack and the underlying wells, thereby forming trenches and the active regions 104 protruding from between trenches, in accordance with some embodiments. The patterned mask layer 105 may be a patterned photoresist layer and/or a patterned hard mask layer. The portion of the wells protruding from between the trenches serves as the lower fin elements 104L of the active regions 104, in accordance with some embodiments. The remainder of the epitaxial stack (including the first semiconductor layers 106 and the second semiconductor layers 108) serves as the upper fin elements of the active regions 104, in accordance with some embodiments.

FIG. 3B illustrates the semiconductor structure 100 after the formation of an isolation structure 110, in accordance with some embodiments of the disclosure. An isolation structure 110 is formed over the substrate 102 to surround the lower fin elements 104L of the active regions 104, in accordance with some embodiments. The isolation structure 110 is configured to electrically isolate active regions 104 of the semiconductor structure 100 and is also referred to as a shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), LPCVD, PECVD, HDP-CVD, or HARP), ALD, another suitable technique, or a combination thereof.

A planarization process is performed on the insulating material to remove a portion of the insulating material above the active regions 104, in accordance with some embodiments. The planarization process may be chemical mechanical polishing (CMP), etching back process, or a combination thereof. In some embodiments, the patterned mask layer 105 is also removed in the planarization process. The insulating material is then recessed by an etching process (such as dry plasma etching and/or wet chemical etching) to expose the sidewalls of the mask layers 109 and the upper fin elements of the active regions 104, in accordance with some embodiments. In some embodiments, the sidewalls of the top portion of the lower fin elements 104L are partially exposed.

FIG. 3C illustrates the semiconductor structure 100 after the formation of dummy gate structures 112, in accordance with some embodiments of the disclosure. The dummy gate structures 112 are formed across the active regions 104 and the isolation structure 110, as shown in FIG. 3C, in accordance with some embodiments. The dummy gate structures 112 surround the channel regions of the active regions 104, in accordance with some embodiments. The dummy gate structures 112 are configured as sacrificial structures and will be replaced with the final gate stacks, in accordance with some embodiments.

Each of the dummy gate structures 112 includes a dummy gate dielectric layer 114 and a dummy gate electrode layer 116 formed over the dummy gate dielectric layer 114, as shown in FIG. 3C, in accordance with some embodiments. In some embodiments, the dummy gate dielectric layer 114 extends along the mask layers 109 and the upper fin elements of the active regions 104 and the isolation structure 110. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO. In some embodiments, the dummy gate electrode layer 116 is made of semiconductor materials such as polysilicon or poly-silicon germanium.

In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112 using photolithography and etching processes. The patterning process may include forming patterned hard mask layers 111 and 113. In some embodiments, the patterned hard mask layer 111 is a SiN layer, and the patterned hard mask layer 113 is a SiO layer.

FIGS. 3D-1 and 3D-2 illustrate the semiconductor structure 100 after the formation of gate spacer layers 118, fin spacer layers 120 and source/drain recesses 126, in accordance with some embodiments of the disclosure. Gate spacer layers 118 are formed along opposite sidewalls of the dummy gate structures 112, and fin spacer layers 120 are formed along opposite sidewalls of the active regions 104, as shown in FIGS. 3D-1 and 3D-2, in accordance with some embodiments. The gate spacer layers 118 extend in the Y direction and across the active regions 104 and the isolation structure 110, in accordance with some embodiments. The fin spacer layers 120 extend in the X direction, in accordance with some embodiments.

The gate spacer layers 118 are used to offset the subsequently formed source/drain features and separate the source/drain features from the gate structures 112, in accordance with some embodiments. The fin spacer layers 120 are used to confine the growth of epitaxial material to prevent neighboring source/drain features from merging with each other, in accordance with some embodiments.

In some embodiments, the gate spacer layers 118 and the fin spacer layers 120 are formed from one or more continuous dielectric material(s). For example, in some embodiments, the formation of the gate spacer layers 118 and the fin spacer layers 120 includes globally and conformally depositing spacer layers 122 and 124 over the semiconductor structure 100 using ALD, CVD (such as LPCVD, PECVD or HDP-CVD or a combination thereof, followed by an anisotropic etching process, in accordance with some embodiments.

In some embodiments, the spacer layers 122 and 124 are made of dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the spacer layer 122 and the spacer layer 124 are made of different materials and have different dielectric constant values. For example, the spacer layers 122 and 124 are made of SiOCN with different compositions (e.g., different carbon concentrations) and different dielectric constants. In some other embodiments, the spacer layers 122 and 124 are the same material.

After the anisotropic etching process, the vertical portions of the spacer layers 122 and 124 left remaining on the opposite sides of the dummy gate structures 112 form the gate spacer layers 118, in accordance with some embodiments. The vertical portions of the spacer layers 122 and 124 left remaining on the opposite sides of the active regions 104 form the fin spacer layers 120, in accordance with some embodiments.

An etching process is performed to recess the source/drain regions of the active regions 104, thereby forming source/drain recesses 126, as shown in FIGS. 3D-1 and 3D-2, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 118 and the dummy gate structure 112 may serve as etch masks such that the source/drain recesses 126 are formed self-aligned on opposite sides of the dummy gate structure 112, in accordance with some embodiments. The bottoms of the source/drain recesses 126 extend into the lower fin elements 104L, in accordance with some embodiments.

In the etching process, the isolation structure 110 is also recessed, thereby forming STI recesses, in accordance with some embodiments. In some embodiments, the bottom of the STI recess extends downward to a deeper position than the bottom of the source/drain recess 126. In some other embodiments, the isolation structure 110 may be unrecessed, or slightly recessed. In addition, the fin spacer layers 120 are also recessed in the etching process.

FIGS. 3E-1 and 3E-2 illustrate the semiconductor structure 100 after the formation of inner spacer layers 128, in accordance with some embodiments of the disclosure. An etching process is performed to laterally recess, from the source/drain recesses 126, the first semiconductor layers 106 of the active regions 104 thereby forming notches, and then inner spacer layers 128 are formed in the notches, as shown in FIG. 3E-1, in accordance with some embodiments. The inner spacer layers 128 are formed to abut the recessed side surfaces of the first semiconductor layers 106, in accordance with some embodiments. In some embodiments, the inner spacer layers 128 extend directly below the gate spacer layers 118.

In some embodiments, the inner spacer layers are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN. In some embodiments, the formation of the inner spacer layers 128 includes depositing a dielectric material for the inner spacer layers over the semiconductor structure 100 to overfill the notches, and then etching away the portion of the dielectric material outside the notches.

FIGS. 3F-1 and 3F-2 illustrate the semiconductor structure 100 after the formation of semiconductor isolation features 130, dielectric isolation features 132 and source/drain features 134N and 134P, in accordance with some embodiments of the disclosure. Semiconductor isolation features 130 are formed in the source/drain recesses 126 on the lower fin elements 104L using an epitaxial growth process, as shown in FIGS. 3F-1 and 3F-2, in accordance with some embodiments. The epitaxial growth process may be MBE, MOCVD, or VPE, another suitable technique, or a combination thereof. In some embodiments, the semiconductor isolation features 130 are made of undoped epitaxial material such as intrinsic silicon, intrinsic silicon germanium and/or another suitable semiconductor material.

Dielectric isolation features 132 are formed on the semiconductor isolation features 130, in accordance with some embodiments. In some embodiments, the dielectric isolation features 132 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation features 132 are formed by forming a deposition process, followed by an etching-back process. In some embodiments, the dielectric isolation features 132 may be further formed on the upper surface of the isolation structure 110 in the STI recesses.

Source/drain features 134N and 134P are formed in and/or over the source/drain regions of the active regions 104, as shown in FIGS. 3F-1 and 3F-2, in accordance with some embodiments. The source/drain features 134N and 134P are grown in the source/drain recesses 126 from the exposed surfaces of the second semiconductor layers 108 using an epitaxial growth process, as shown in FIGS. 3F-1 and 3F-2, in accordance with some embodiments. In some embodiments, the source/drain features 134N are formed in the p-type well, and the source/drain features 134P are formed in the n-type well. The epitaxial growth process may be MBE, MOCVD, or VPE, another suitable technique, or a combination thereof.

The source/drain features 134N are formed over the p-type well, and the source/drain features 134P are formed over the n-type well, in accordance with some embodiments. In some embodiments, the source/drain features 134N and 134P abut the inner spacer layers and the second semiconductor layers 108. In some embodiments, the source/drain features 134N and 134P are made of any suitable semiconductor material for n-type semiconductor devices or p-type semiconductor devices.

The source/drain features 134N are made of semiconductor materials such as SiP, SiAs, SiCP, SiC, Si, GaAs, another suitable semiconductor material, or a combination thereof. In some embodiments, the source/drain features 134N are doped with the n-type dopant during the epitaxial growth process. For example, the n-type dopant may be phosphorous (P) or arsenic (As). For example, the source/drain features 134N may be the epitaxially grown Si doped with phosphorous to form silicon:phosphor (Si:P) source/drain features and/or arsenic to form silicon:arsenic (Si:As) source/drain features.

The source/drain features 134P are made of semiconductor materials such as SiGe, Si, GaAs, another suitable semiconductor material, or a combination thereof. In some embodiments, the source/drain features 134P are doped with the p-type dopant during the epitaxial growth process. For example, the p-type dopant may be boron (B) or BF₂. For example, the source/drain features 134P may be the epitaxially grown SiGe doped with boron (B) to form a silicon germanium:boron (SiGe:B) source/drain feature.

The n-type source/drain features 134N and the p-type source/drain features 134P may be formed separately. The respective concentrations of the dopants in the source/drain features 134N and 134P in a range from about 1×10¹⁹ cm⁻³ to about 6×10²¹ cm⁻³. In some embodiments, the source/drain features 134N/134P may be multilayered structures, e.g., including sequentially formed epitaxial layers L1 and L2, as shown in FIG. 3F-1. In some embodiments, the concentration of the dopant in the epitaxial layer L2 is higher than the concentration of the dopant in the epitaxial layer L1, e.g., by 1-2 orders. An annealing process may be performed on the semiconductor structure 100 to activate the dopants in the source/drain features 134N and 134P, in accordance with some embodiments.

FIGS. 3G-1, 3G-2 and 3G-3 illustrate the semiconductor structure 100 after the formation of a contact etching stop layer 136 and an interlayer dielectric layer 138, in accordance with some embodiments of the disclosure. A contact etching stop layer 136 is formed over the semiconductor structure 100 to cover the source/drain features 134N and 134P, as shown in FIGS. 3G-1, 3G-2 and 3G-3, in accordance with some embodiments. The contact etching stop layer 136 is further formed along, and covers, the sidewalls of the gate spacer layers 118 and the fin spacer layers 120 and the exposed surfaces of the isolation structure 110 and the dielectric isolation features 132, in accordance with some embodiments.

In some embodiments, the contact etching stop layer 136 is made of dielectric material, such as silicon nitride (SiN), silicon oxynitride (SiON), silicon oxide (SiO₂), silicon oxynitride (SiON), silicon carbide (SiC), oxygen-doped silicon carbide (SiC:O), oxygen-doped silicon carbonitride (Si(O)CN), or a combination thereof. In some embodiments, a dielectric material for the contact etching stop layer 136 is globally and conformally deposited over the semiconductor structure 100 using CVD (such as LPCVD, PECVD, HDP-CVD, or HARP), ALD, another suitable method, or a combination thereof.

Afterward, an interlayer dielectric layer 138 is formed over the contact etching stop layer 136, as shown in FIGS. 3G-1, 3G-2 and 3G-3, in accordance with some embodiments. The interlayer dielectric layer 138 overfills the STI recesses and the space between the dummy gate structures 112, in accordance with some embodiments. In some embodiments, the interlayer dielectric layer 138 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the dielectric material for the interlayer dielectric layer 138 is deposited using such as CVD (such as HDP-CVD, PECVD, HARP or FCVD), another suitable technique, or a combination thereof. The dielectric materials for the contact etching stop layer 136 and the interlayer dielectric layer 138 above the top surface of the dummy gate electrode layer 116 are removed using such as CMP, in accordance with some embodiments. In some embodiments, the patterned mask layers 111 and 113 are also removed.

FIGS. 3H-1, 3H-2 and 3H-3 illustrate the semiconductor structure 100 after the formation of a gate-cut opening 140A, in accordance with some embodiments of the disclosure. A patterning process is performed on the semiconductor structure 100 to form a gate-cut opening 140A through the dummy gate structure 112, as shown in FIGS. 3H-1 and 3H-3, in accordance with some embodiments. The dummy gate structure 112 is cut through by the gate-cut opening 140A into several dummy gate segments 112A, as shown in FIG. 3H-3, in accordance with some embodiments.

The patterning process includes forming a patterned mask layer (not shown) over the semiconductor structure 100, in accordance with some embodiments. In some embodiments, the patterned mask layer may be a patterned photoresist layer and/or a patterned hard mask layer. In some embodiments, the patterned mask layer has a trench pattern located directly above the isolation structure 110 between the active regions 104, in accordance with some embodiments. In some embodiments, the trench pattern extends in the X direction and across one or more dummy gate structures 112. The trench pattern may be also referred to as a cut poly gate (CPO) pattern. In some embodiments, the width of the trench pattern in the Y direction is narrower than the spacing S2 between the active regions 104₂ and 104₃.

The patterning process further includes performing an etching process on the semiconductor structure 100 using the patterned mask layer, in accordance with some embodiments. The etching process may include an anisotropic etching step and an isotropic etching step, in accordance with some embodiments. The anisotropic etching step may be dry plasma etching. The anisotropic etching step vertically etches the portion of the dummy gate electrode layers 116 exposed from the trench pattern, thereby forming an opening between the active regions 104, in accordance with some embodiments. In some embodiments, the opening is narrower than the spacing S2 between the active regions 104₂ and 104₃. The anisotropic etching step is performed until the opening extends to the upper surface of the isolation structure 110, in accordance with some embodiments. The patterned mask layer may be removed in the etching process and/or by an additional removal process (e.g., ashing, etching or wet strip process).

In the anisotropic etching step, the portions of the gate spacer layers 118, the contact etching stop layer 136 and the interlayer dielectric layer 138, exposed from the trench pattern are slightly etched to form an opening 140B, as shown in FIGS. 3H-1 and 3H-2, in accordance with some embodiments. The opening 140B does not extend between the source/drain features 134N and 134P due to the difference in the etching selectivity between the dummy gate electrode layers 116 and these dielectric layers, in accordance with some embodiments. In some other embodiments, the opening 140B may extend between the source/drain features 134N and 134P.

The isotropic etching step is then performed to laterally etch, from the opening, the portion of dummy gate electrode layers proximate to and between the active regions 104₂ and 104₃, in accordance with some embodiments. The opening is laterally enlarged thereby forming the gate-cut opening 140A, as shown in FIGS. 3H-1 and 3H-3, in accordance with some embodiments. The isotropic etching process may be an isotropic etching process such as dry chemical etching, remote plasma etching or wet chemical etching, and/or a combination thereof. The isotropic etching process is performed until the dummy gate dielectric layer 114 along the sidewalls of the active regions 104₂ and 104₃ is exposed, in accordance with some embodiments.

In the isotropic etching process, the dummy gate dielectric layer 114, the gate spacer layers 118, the contact etching stop layer 136 and the interlayer dielectric layer 138 are substantially unetched due to the difference in etching selectivity, in accordance with some embodiments. An upper portion of the gate-cut opening 140A above the active regions 104 may be wider in the Y direction than the lower portion of the gate-cut opening 140A between the active regions 104, as shown in FIGS. 3H-1 and 3H-3, in accordance with some embodiments.

FIG. 3I-1 illustrates the semiconductor structure 100 after the removal of the dummy gate dielectric layer 114 and the formation of semiconductor features 142, in accordance with some embodiments of the disclosure. FIG. 3I-2 is a plan view taken along line A-A of FIG. 3I-1. The portion of the dummy gate dielectric layer 114 exposed from the gate-cut opening 140A is removed using an etching process, as shown in FIG. 3I-1, in accordance with some embodiments. The active regions 104₂ and 104₃ are exposed from the gate-cut opening 140A, in accordance with some embodiments. The etching process may be an anisotropic etching process such as dry plasma etching, an isotropic etching process such as dry chemical etching, remote plasma etching or wet chemical etching, or a combination thereof.

In some embodiments, the edges of the dummy gate segments 112A terminate on the top surfaces of the active regions 104₂ and 104₃. The gate-cut openings 140A are formed self-aligned at the location of the dummy gate structures 112 between the active regions 104₂ and 104₃ and achieve a minimized end-cap dimension, in accordance with some embodiments.

Semiconductor features 142 are selectively grown on the sidewalls of the second semiconductor layers 108 of the active regions 104₂ and 104₃ exposed from the gate-cut opening 140A using an epitaxial growth process, as shown in FIGS. 3I-1 and 3I-2, in accordance with some embodiments. The semiconductor features 142 are also grown on the exposed sidewalls of the top portions of the lower fin elements 104L, in accordance with some embodiments. The semiconductor features 142 are sandwiched between the gate spacer layers 118, as shown in FIG. 3I-2, in accordance with some embodiments. The epitaxial growth process may be MBE, MOCVD, or VPE, another suitable technique, or a combination thereof.

In some embodiments, the semiconductor features 142 are configured as portions of channel layers of the resulting semiconductor devices. In some embodiments, the semiconductor features 142 has a thickness T4 (the dimension in the Y direction) in a range from about 2 nm to about 20 nm. The semiconductor features grown on the dummy gate electrode layers 116 are denoted as 143, in accordance with some embodiments. In some embodiments, the exposed surfaces of the mask layer 109 and the first semiconductor layers 106 of the active regions 104₂ and 104₃ remain exposed.

In some embodiments, the semiconductor features 142 are made of semiconductor materials such as Si or SiGe. In some embodiments, the semiconductor features 142 are made of the same material as the second semiconductor layers 108, and have the same composition as the second semiconductor layers 108. In an embodiment, the semiconductor features 142 and the second semiconductor layers 108 are made of pure or substantially pure silicon. In an embodiment, the semiconductor features 142 and the second semiconductor layers 108 are made of SiGe with the same Ge concentration.

In some other embodiments, the semiconductor features 142 and the second semiconductor layers 108 have different compositions, for example, they are made of SiGe with different Ge concentrations. Although the interfaces between the semiconductor features 142 and the second semiconductor layers 108 are shown in FIGS. 3I-1 and 3I-2, there may be no interfaces between the semiconductor features 142 and the second semiconductor layers 108.

FIG. 3J illustrates the semiconductor structure 100 after the formation of a wall structure 144, in accordance with some embodiments of the disclosure. A wall structure 144 is formed in the gate-cut opening 140A, as shown in FIG. 3J, in accordance with some embodiments. The formation of the wall structure 144 includes conformally depositing a dielectric lining layer 146 along the semiconductor structure 100 to partially fill the gate-cut opening 140A, depositing a dielectric bulk layer 148 over the dielectric lining layer 146 to overfill the gate-cut opening 140A, and planarizing the dielectric lining layer 146 and the dielectric bulk layer 148, in accordance with some embodiments. The dielectric lining layer 146 extends vertically in a wavy shape along the sidewalls of the active regions 104₂ and 104₃, in accordance with some embodiments.

The dielectric lining layer 146 and the dielectric bulk layer 148 are made of low-k dielectric material (e.g., with k-value less than 7.9), such as silicon nitride (SiN), silicon oxynitride (SiON), silicon oxide (SiO₂), silicon carbon nitride (SiCN), oxygen-doped silicon carbide (SiC:O), oxygen-doped silicon carbonitride (Si(O)CN), or another suitable dielectric material. In some embodiments, the dielectric lining layer 146 and the dielectric bulk layer 148 are made of different materials and have different dielectric constant values. For example, the dielectric lining layer 146 is made of silicon oxide, and the dielectric bulk layer 148 is made of silicon nitride. In some embodiments, the dielectric lining layer 146 has a lower dielectric constant than the dielectric bulk layer 148. In some embodiments, the dielectric bulk layer 148 has a higher etching resistance than the dielectric lining layer 146.

The deposition processes may be ALD, CVD (such as LPCVD, PECVD or HDP-CVD or a combination thereof, in accordance with some embodiments. The planarization process may be CMP or an etching-back process, in accordance with some embodiments. The planarization process is performed until the upper surface of the gate electrode layer 116 is exposed, in accordance with some embodiments. In some embodiments, the thickness T5 (i.e., the dimension in the Y direction) of the dielectric lining layer 146 is less than 5 nm, e.g., 2-5 nm.

FIG. 3K illustrates the semiconductor structure 100 after the formation of gate trenches 150. The dummy gate electrode layer 116 of the dummy gate structures 112 and the semiconductor features 143 are removed using an etching process to form gate trenches 150, as shown in FIG. 3K, in accordance with some embodiments. The etching process is performed until the dummy gate dielectric layer 114 is exposed, in accordance with some embodiments. In some embodiments, the etching process may be an anisotropic etching process such as dry plasma etching, an isotropic etching process such as dry chemical etching, remote plasma etching or wet chemical etching, or a combination thereof.

FIG. 3L illustrates the semiconductor structure 100 after the removal of the gate dielectric layer 114. The gate dielectric layer 114 of the dummy gate structures 112 are removed using an etching process until the channel regions of the active regions 104 are exposed, as shown in FIG. 3L, in accordance with some embodiments. In some embodiments, the etching process may be an anisotropic etching process such as dry plasma etching, an isotropic etching process such as dry chemical etching, remote plasma etching or wet chemical etching, or a combination thereof.

FIGS. 3M-1 and 3M-2 illustrate the semiconductor structure 100 after the removal of the first semiconductor layer 106. An etching process is performed on the first semiconductor layers 106 of the active regions 104 to form gaps 152, as shown in FIGS. 3M-1 and 3M-2, in accordance with some embodiments. The etching processes include an anisotropic etching process such as dry plasma etching, an isotropic etching process such as dry chemical etching, remote plasma etching or wet chemical etching, or a combination thereof. The inner spacer layers 128 may protect the source/drain features 134N and 134P from being damaged, in accordance with some embodiments. In some embodiments, the gaps 152 expose the sidewalls of the inner spacer layers 128 facing the channel regions. In some embodiments, the gate trenches 150 expose the sidewalls of the gate spacer layers 118 facing the channel regions.

After the etching processes, the three main surfaces of the second semiconductor layers 108 are exposed, as shown in FIG. 3M-2, in accordance with some embodiments. The other main surfaces of the second semiconductor layers 108 facing the wall structure 144 remain covered by the semiconductor feature 142. Each of the second semiconductor layers 108 and the neighboring corresponding semiconductor feature 142 combine to form a nanostructure 154, as shown in FIG. 3M-2, in accordance with some embodiments.

The nanostructures 154 are stacked vertically over the lower fin elements 104, and spaced apart from one other, in accordance with some embodiments. The nanostructures 154 function as channel layers of the resulting semiconductor devices (e.g., nanostructure transistors such as GAA transistors), in accordance with some embodiments. The formation of the semiconductor features 142 may increase the effective channel width, which may increase the on-state current (e.g., Isat) of the transistors, thereby boosting the performance (e.g., DC performance) of the resulting semiconductor device.

FIG. 3N-1 illustrates the semiconductor structure 100 after trimming processes. FIG. 3N-2 is an enlarged view of FIG. 3N-1 to illustrate more detail of the semiconductor feature 142 and neighboring components. A first trimming process is performed to laterally remove the dielectric lining layer 146, as shown in FIGS. 3N-1 and 3N-2, in accordance with some embodiments. The first trimming process may include an isotropic etching process such as dry chemical etching, remote plasma etching or wet chemical etching, or a combination thereof. The first trimming process is performed until the dielectric bulk layer 148 is exposed, in accordance with some embodiments.

The remaining portions of the dielectric lining layer 146 left between the nanostructures 154 and the dielectric bulk layer 148 are referred to as dielectric features 146A, in accordance with some embodiments. The dielectric features 146A are also located between the mask layer 109 and the dielectric bulk layer 148, in accordance with some embodiments. The remaining portion of the dielectric lining layer 146 left between the isolation structure 110 and the dielectric bulk layer 148 is referred to as a dielectric feature 146B, in accordance with some embodiments.

The first trimming process further vertically recesses the dielectric features 146A from the top side and bottom side of the dielectric features 146A, in accordance with some embodiments. As a result, the first trimming process creates a space 155 directly between the inner sidewall (facing the wall structure 144) of the second semiconductor layers 108 and the dielectric bulk layer 148, as shown in FIG. 3N-2, in accordance with some embodiments. The space 155 will be filled by a gate dielectric layer, which may help improve the gate control capability over the channel layer of the transistors without increasing the end-cap dimension.

A second trimming process may be optionally performed to shape the nanostructures 154 to have a desired profile, in accordance with some embodiments. For example, the sharp corners of the second semiconductor layers 108 are shaped into round corners, as shown in FIGS. 3N-1 and 3N-2, in accordance with some embodiments. The second trimming process may include an isotropic etching process such as dry chemical etching, remote plasma etching or wet chemical etching, or a combination thereof. In some embodiments, the trimmed second semiconductor layer 108 has a thickness T2′ that is less than the thickness T2 due to the consumption of the second semiconductor layer 108 in the second trimming process.

Each of the dielectric features 146A has a top surface that is located at a lower level than the top surface 108T of the corresponding semiconductor layer 108, in accordance with some embodiments. Each of the dielectric features 146A has a bottom surface that is located at a higher level than the bottom surface 108B of the corresponding semiconductor layer 108, as shown in FIG. 3N-2, in accordance with some embodiments. In some embodiments, the dimension of the dielectric features 146A in the Z direction is less than the thickness T2′ of the corresponding semiconductor layer 108.

In some embodiments, the semiconductor features 142 are also recessed in the second trimming process. The dimension of the trimmed semiconductor features 142 in the Z direction may gradually decrease toward the dielectric features 146A. The second trimming process enlarges the space 155, in accordance with some embodiments. Therefore, the gate control capability over the channel layer of the transistors may be further improved.

In some embodiments, the top surface (or the lowermost point of the top surface) of the dielectric feature 146A is distant from the top surface 108T of the semiconductor layer 108 by a distance D1. In some embodiments, the bottom surface (or the topmost point of the bottom surface) of the dielectric feature 146A is distant from the bottom surface 108B of the semiconductor layer 108 by a distance D1′. In some embodiments, the distances D1 and D1′ are less than bout 2 nm, e.g., in a range from 0.5 nm about to about 2 nm. If the distance D1 and D1′ is too small, the gate control capability may be not sufficiently improved. If the distances D1 and D1′ are too great, the total cell capacitance may increase. The value of the distances D1 and D1′ may depend on the application of the resulting semiconductor device.

In some other embodiments, each of the dielectric features 146A has a top surface located substantially level to (i.e., D1 is zero) the top surface 108T of the corresponding semiconductor layer 108, and each of the dielectric features 146A has a bottom surface substantially level to (i.e., D1′ is zero) the bottom surface 108B of the corresponding semiconductor layer 108.

In some embodiments, the trimmed semiconductor features 142 remain in direct contact with the dielectric features 146A. In some embodiments, after the first and second trimming processes, the semiconductor features 142 maintain the thickness T4 (in the Y direction), and the dielectric features 146A maintain the thickness T5 (in the Y direction). In some other embodiments, the trimmed semiconductor features 142 may be separate from the dielectric features 146A by increasing the etching amount of the first trimming process and/or increasing the etching amount of the second trimming process. In yet other embodiments, the dielectric features 146A may be completely removed in the first trimming process.

FIG. 3O illustrates the semiconductor structure 100 after the formation of an interfacial layer 156, a gate dielectric layer 158 and metal gate electrode layer. An interfacial layer 156 is formed on the exposed surfaces of the nanostructures 154 and the exposed surfaces of the lower fin elements 104L, in accordance with some embodiments. The interfacial layer 156 wraps around the nanostructures 154, in accordance with some embodiments. In some embodiments, the interfacial layer 156 is made of a chemically formed silicon oxide. In some embodiments, the interfacial layer 156 is nitrogen-doped silicon oxide. In some embodiments, the interfacial layer 156 is formed using one or more cleaning processes such as including ozone (O₃), ammonia hydroxide-hydrogen peroxide-water mixture, and/or hydrochloric acid-hydrogen peroxide-water mixture. Semiconductor material from the second semiconductor layers 108, the semiconductor features 142 and the lower fin elements 104L is oxidized to form the interfacial layer 156, in accordance with some embodiments.

The gate dielectric layer 158 is formed conformally along the interfacial layer 156 to wrap around the nanostructures 154 and the mask layers 109, in accordance with some embodiments. The gate dielectric layer 158 is also conformally formed along the sidewalls of the gate spacer layers 118 facing the channel region, in accordance with some embodiments. The gate dielectric layer 158 is also conformally formed along the sidewalls of the inner spacer layers 128 facing the channel region, in accordance with some embodiments. In addition, the gate dielectric layer 158 is also conformally formed along the sidewalls of the wall structure 144.

The gate dielectric layer 158 fills the space 155 and is in direct contact with dielectric features 146A and 146B and the dielectric bulk layer 148, in accordance with some embodiments. As a result, the gate dielectric layer 158 may approach a closer position to the inner side surface (facing the wall structure 144) of the second semiconductor layers 108, in accordance with some embodiments. Therefore, the gate control capability over the channel layer of the transistors may be improved, which may improve the short channel effect.

The gate dielectric layer 158 may be a high-k dielectric layer. In some embodiments, the high-k dielectric layer is dielectric material with a high dielectric constant (k value), for example, greater than 10, such as greater than 20, such as greater than 30. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), a combination thereof, or another suitable material. The high-k dielectric layer may be deposited using ALD, PVD, CVD, and/or another suitable technique.

The metal gate electrode layer is formed to overfill remainders of the gate trenches 150 and gaps 152, in accordance with some embodiments. In some embodiments, the metal gate electrode layer is made of more than one conductive material, for example, a p-type work function layer 162P, an n-type work function layer 162N, a cap layer 164, a barrier layer 166, and a metal fill layer 168, as shown in FIG. 3O.

In some embodiments, the p-type work function layer 162P is formed on the gate dielectric layer 158 in the n-type well. In some embodiments, the n-type work function layer 162N is formed on the gate dielectric layer 158 in the p-type well and on the p-type work function layer 162P in the n-type well. A patterning process (e.g., including photolithography and etching processes) may be performed on the p-type work function layer 162P to remove the p-type work function layer 162P from the p-type well. In some embodiments, the work function metal layers 162P and 162N have selected work functions to enhance the device performance (e.g., threshold voltage) for n-channel FETs or p-channel FETs. For example, the p-type work function metal layer 162P is made of TiN, WN, WCN, TaN, Ru, Co, W, or another suitable p-type work function metal, and the work function metal layer 162N is made of Ti, Ag, Al, TiAl, TiAlN, TiAlC, TaAl, TaC, TaCN, TaSiN, TaAlC, Mn, Zr, or another suitable n-type work function metal.

The cap layer 164 may protect the n-type work function layer 162N from being oxidized, and may be made of silicon, titanium, or metal nitride such as TiN or TSN (titanium nitride doped with silicon). The barrier layer 166 may be made of Ti, TiN, Ta, or TaN. The metal fill layer 168 may be made of W, Co, or Ru. These gate electrode materials may be deposited using ALD, PVD, CVD, e-beam evaporation, or another suitable technique.

Due to the formation of the mask layer 109, the gate electrode materials around the topmost nanostructures 154 may have a similar configuration and profile as the configuration and profile of the gate electrode materials around the underlying nanostructures 154, which may reduce the variation of the performance (e.g., threshold voltage) of the resulting semiconductor device.

FIGS. 3P-1 and 3P-2 illustrate the semiconductor structure 100 after a planarization process. A planarization process such as CMP may be performed on the semiconductor structure 100 to remove the materials of the gate dielectric layer 158 and the metal gate electrode layer formed above the top surface of the interlayer dielectric layer 138 and the top surface of the wall structure 144, as shown in FIGS. 3P-1 and 3P-2, in accordance with some embodiments. The interfacial layer 156, the gate dielectric layer 158 and the gate electrode materials (including the p-type work function layer 162P, the n-type work function layer 162N, the cap layer 164, the barrier layer 166, and the metal fill layer 168) combine to form final gate stacks 170, as shown in FIGS. 3P-1 and 3P-2, in accordance with some embodiments. The final gate stacks 170 wrap around the nanostructures 154, in accordance with some embodiments. The final gate stacks 170 include gate segments 170A and 170B which are physically and electrically isolated from each other by the wall structure 144, in accordance with some embodiments.

The final gate stacks 170 engage the channel regions so that current can flow between the source/drain features 134N/134P during operation. The gate segments 170A that are wrapped around the nanostructures 154 combine with the neighboring source/drain features 134N to form n-channel nanostructure transistors (e.g., NMOSFET in FIG. 2) in the p-type well, in accordance with some embodiments. The gate segments 170B that are wrapped around the nanostructures 154 combine with the neighboring source/drain features 134P to form p-channel nanostructure transistors (e.g., PMOSFET in FIG. 2) in the n-type well, in accordance with some embodiments.

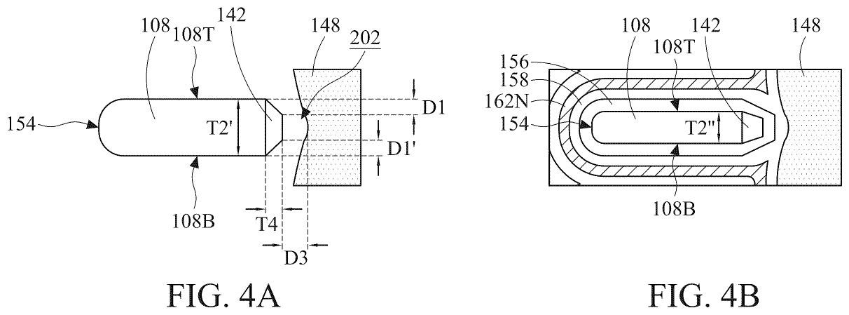

FIGS. 3Q-1, 3Q-2 and 3Q-3 illustrate the semiconductor structure 100 after the formation of cut-gate structures 172. FIG. 3Q-4 is an enlarged view of FIG. 3Q-3 to illustrate more detail of the semiconductor feature 142 and neighboring components. FIG. 3Q-5 is a plan view taken along line A-A of FIG. 3Q-1. Gate-cut structures 172 are formed through the final gate stacks 170, the gate spacer layers 118, the interlayer dielectric layer 128 and the contact etching stop layer 126, as shown in FIGS. 3Q-2 and 3Q-3, in accordance with some embodiments. The final gate stacks 170 are further cut through by the gate-cut structures 172 into more gate segments 170A1, 170A2, 170B1 and 170B2, which are physically and electrically isolated from each other, as shown in FIG. 3Q-3, in accordance with some embodiments. The gate-cut structures 172 may be also referred to as cut metal gate (CMG) patterns.

The gate-cut structures 172 are made of a low-k dielectric material (e.g., with k-value less than 7.9) such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate-cut structures 172 include dielectric material with a dielectric constant value greater than 7.9, such as LaO, AlO, AlON, ZrO, HfO, ZnO, ZrN, ZrAlO, TiO, TaO, YO, TaCN, or a combination thereof.

The formation of the gate-cut structures 172 includes patterning the semiconductor structure 100 to form gate-cut openings using photolithography and etching processes, depositing a dielectric material to overfill the gate-cut openings, in accordance with some embodiments. In some embodiments, the gate-cut openings may extend into the isolation structure 110. A planarization process (e.g., CMP, etching back process, or a combination thereof) is then performed on the dielectric material, the final gate stacks 170, the gate spacer layers 118, the contact etching stop layer 136 and the interlayer dielectric layer 158 until the mask layers 109 are exposed, as shown ni FIG. 3Q-3, in accordance with some embodiments.

Because variations in the transistor threshold voltages caused by the cutting process of the final gate stacks 170 need to be considered, the photolithography process for forming the gate-cut structures 172 (CMG patterns) may require higher overlay and/or critical dimension uniformity requirements. On the other hand, because the wall structures 144 (CPO patterns) are formed before the final gate stacks 170 and self-aligned at the location of the dummy gate structures 112 between the active regions 104, the formation of the wall structure 144 may be less constrained by the overlay and/or critical dimension uniformity requirements of the photolithography process. Therefore, the formation of the wall structure 144 may facilitate scaling down the spacing S2 between the active regions 104₂ and 104₃, and thus help achieve scaling down the cell height of the cell region.

In addition, the wall structure 144 may achieve smaller end-cap dimensions, and thus the overlapping area between the source/drain features 134N/134P and the final gate stack 170 may be minimized. As a result, the total cell capacitance of the resulting semiconductor device may be reduced, and the performance (e.g., speed) of the resulting semiconductor device may be enhanced. In some embodiments, the total cell parasitic capacitance is reduced by about 10% to about 15%, and the power efficiency (peff) is increased by about 10% to about 20%.

The nanostructure 154 may have a thickness T2′ that is less than thickness T2′ due to the formation of the interfacial layer 156, as shown in FIG. 3Q-4, in accordance with some embodiments. In some embodiments, a portion of the gate dielectric layer 158 extending over the top surface of the nanostructure 154 has a lowermost point 158A1. The lowermost point 158A1 is located directly between the inner sidewall (facing the wall structure 144) of the second semiconductor layers 108 and the dielectric bulk layer 148, in accordance with some embodiments. In some embodiments, a portion of the gate dielectric layer 158 extending under the bottom surface of the nanostructure 154 has a topmost point 158B1. The topmost point 158B1 is located directly between the inner sidewall (facing the wall structure 144) of the second semiconductor layers 108 and the dielectric bulk layer 148, in accordance with some embodiments. As a result, the gate dielectric layer 158 may approach a closer position to the inner side surface of the second semiconductor layers 108, and thus the gate control capability over the channel layer of the transistors may be further improved.

In some embodiments, the lowermost point 158A1 is lower than the top surface 108T of the semiconductor layer 108, and distant from the top surface 108T by a distance D2. In some embodiments, the topmost point 158B1 is higher than the bottom surface 108B of the semiconductor layer 108, and distant from the bottom surface 108B by a distance D2′. In some embodiments, the distances D2 and D2′ are less than bout 2 nm, e.g., in a range from 0.5 nm about to about 2 nm. If the distances D2 and D2′ are too small, the gate control capability may be not sufficiently improved. If the distance D2 and D2′ is too great, the parasitic capacitance may increase. The value of the distance D2 and D2′ may depend on the application of the resulting semiconductor device. Although the interfaces between the interfacial layer 156 and the dielectric features 146A are shown in FIG. 3Q-4, there may be no interfaces between the interfacial layer 156 and the dielectric features 146A.

The second semiconductor layer 108 may be also referred to as a bulk portion of the nanostructure 154, and the semiconductor feature 142 may be also referred to as a protrusion of the nanostructure 154, in accordance with some embodiments. The sidewalls 108S1 and 108S2 of the bulk portion 108 extend in the Y direction and adjoin the source/drain features 134N (or 134P), as shown in FIG. 3Q-5, in accordance with some embodiments. The sidewall 108S3 of the bulk portion 108 extends in the X direction and adjoins the gate segment 170A1 (or 170B1), in accordance with some embodiments. The sidewall 108S4 of the bulk portion 108 extends in the X direction and faces the wall structure 144, and the protrusion 142 of the nanostructure 154 protrudes from the sidewall 108S4 toward the wall structure 144, in accordance with some embodiments. In some embodiments, the protrusion 142 is sandwiched between the gate spacer layers 118. The protrusion 142 of the nanostructure 154 may increase the effective channel width, which may increase the on-state current of the transistors, thereby boosting the performance of the resulting semiconductor device. In some embodiments, DC performance is increased by about 1% to about 10%.

It should be understood that the semiconductor structure 100 may undergo further CMOS processes to form various features over the semiconductor structure, such as a multilayer interconnect structure (e.g., contact plugs, conductive vias, metal lines, inter metal dielectric layers, passivation layers, etc.).

FIGS. 4A and 4B are a modification of the semiconductor structure of FIGS. 3N-2 and 3Q-4 respectively, in accordance with some embodiments. The embodiments of FIGS. 4A and 4B are similar to the embodiments of FIGS. 3A through 3Q-5 except that the dielectric lining layer 146A is completely removed in the first trimming process, as shown in FIG. 4A. A gap 202 is formed between the semiconductor feature 142 and the dielectric bulk layer 148, in accordance with some embodiments. In some embodiments, the gap 202 has a dimension D3 in the Y direction that is less than 5 nm, e.g., 2-5 nm. The dimension D3 may be also referred to as the end-cap dimension. If the dimension D3 is too large, the capacitance cell capacitance may increase. The gate dielectric layer 158 is formed to fill into the gap 202, as shown FIG. 4B, in accordance with some embodiments. Therefore, the gate dielectric layer 158 wrap around the nanostructure 154 along the four main surfaces of the nanostructure 154, and thus the gate control capability may be significantly improved.

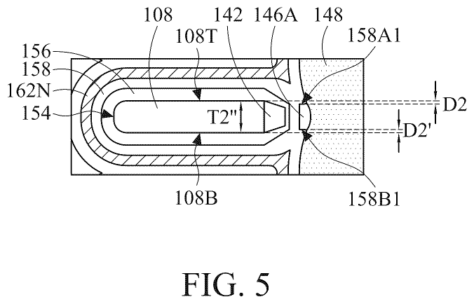

FIG. 5 is a modification of the semiconductor structure of FIG. 3Q-4, in accordance with some embodiments. The embodiments of FIG. 5 are similar to the embodiments of FIGS. 3A through 3Q-5 except that by increasing the etching amount of the first trimming process and/or increasing the etching amount of the second trimming process, the dielectric lining layer 146A is separate from the semiconductor feature 142, as shown in FIG. 5. The gate dielectric layer 158 includes a portion extending between the semiconductor feature 142 and the dielectric lining layer 146A, in accordance with some embodiments.

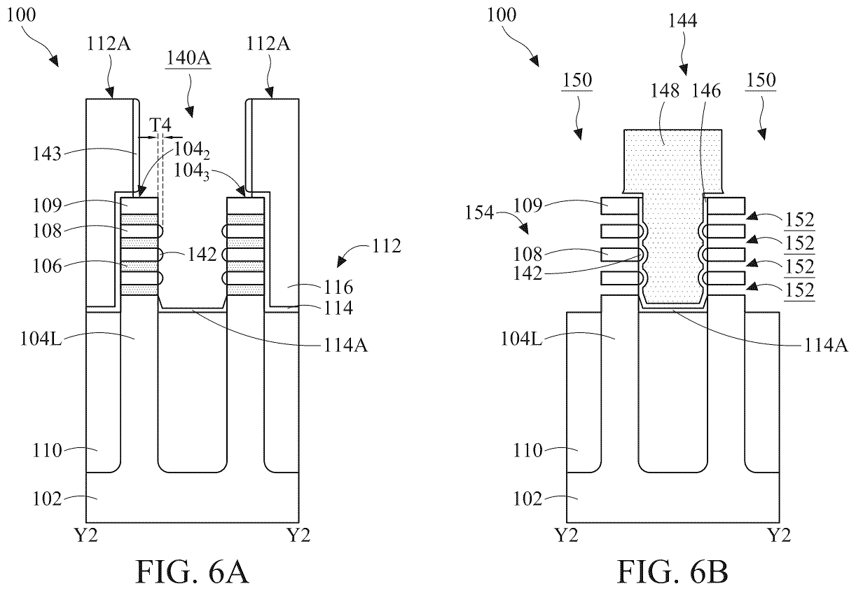

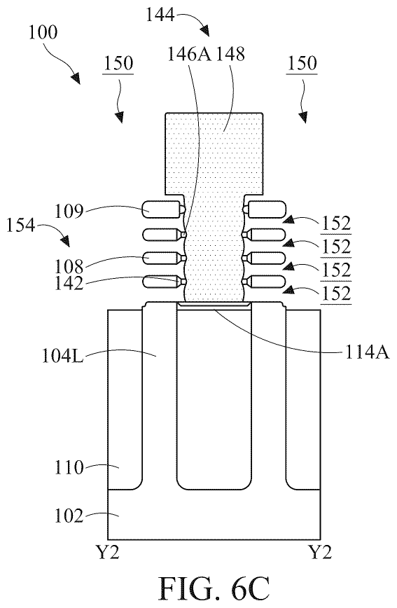

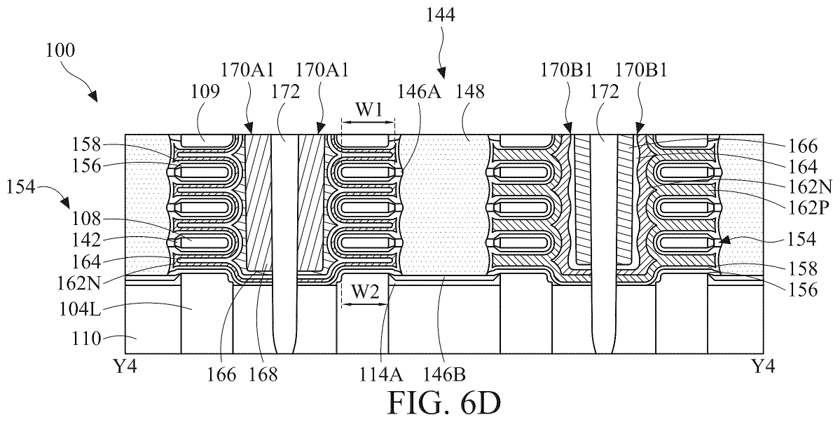

FIGS. 6A through 6D are cross-sectional views illustrating the formation of the semiconductor structure 100 of FIG. 2 at various intermediate stages, in accordance with some embodiments of the disclosure. FIGS. 6A-6C correspond to line Y2-Y2 of FIG. 2, and FIG. 6D corresponds to line Y4-Y4 of FIG. 2. The embodiments of FIGS. 6A through 6D are similar to the embodiments of FIGS. 3A through 3Q-5 except that the semiconductor features 142 are not formed on the lower fin element 104L.

After the portion of the dummy gate dielectric layer 114 exposed from the gate-cut opening 140A is etched, a portion 114A of the dummy gate dielectric layer 114 remains on the upper surface of the isolation structure 110, as shown in FIG. 6A, in accordance with some embodiments. The remaining portion 114A covers the sidewalls of the top portions of the lower fin elements 104L, in accordance with some embodiments. Afterward, semiconductor features 142 are selectively grown on the sidewalls of the second semiconductor layers 108, in accordance with some embodiments.

The steps described above in FIGS. 3J through 3M are performed to form the wall structure 144 in the gate-cut opening 140A, and remove the dummy gate structure 112 and the first semiconductor layers 106, as shown in FIG. 6B, in accordance with some embodiments. The steps described above FIG. 3N are performed to trim the dielectric lining layer 146, and optionally to trim the nanostructures 154, as shown in FIG. 6C, in accordance with some embodiments. The steps described above in FIGS. 3O through 3Q-3 are performed to form the final gate stacks 170 and the gate-cut structures 172, as shown in FIG. 6D, in accordance with some embodiments.

The semiconductor features 142 are not formed on the sidewalls of the top portions of the lower fin elements 104L, and thus the width of the lower fin elements (i.e., the dimension in the Y direction) does not increase, in accordance with some embodiments. As a result, the width W1 of the nanostructure 154 is greater than the width W2 of the lower fin element 104L, in accordance with some embodiments. Therefore, the risk of leakage caused by the bottom planar transistor being formed from the lower fin element 104L is not increased, which may prevent any degradation of the performance (e.g., off-state current (e.g., Isoff)) of the resulting semiconductor device.

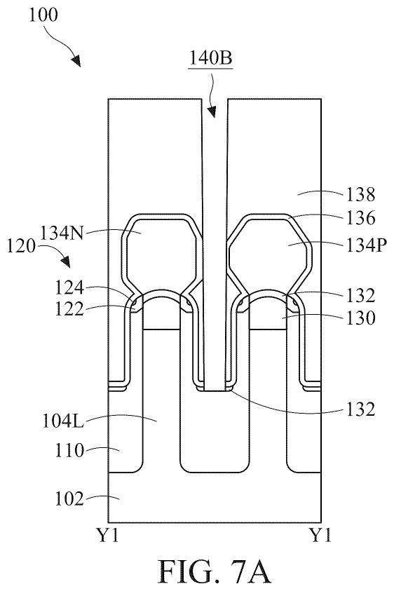

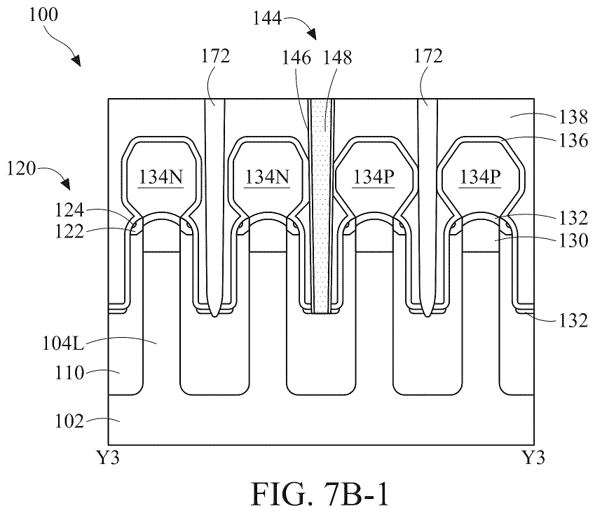

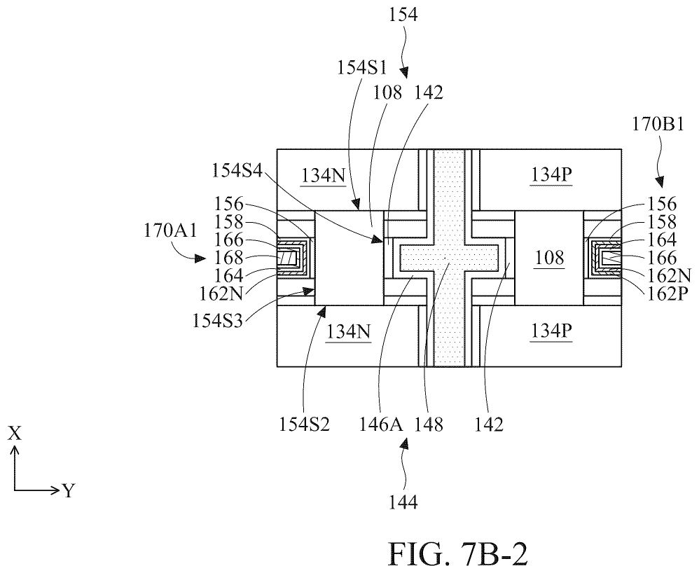

FIGS. 7A and 7B-1 are cross-sectional views illustrating the formation of the semiconductor structure 100 of FIG. 2 at various intermediate stages, in accordance with some embodiments of the disclosure. FIG. 7A corresponds to line Y1-Y1 of FIG. 2, and FIG. 7B-1 corresponds to line Y3-Y3 of FIG. 2. FIG. 7B-2 is a plan view corresponding to line A-A of FIG. 3Q-1. The embodiments of the FIGS. 7A and 7B-1 are similar to the embodiments of FIGS. 3A through 3Q-5 except that the wall structure 144 extends between the source/drain features 134N and 134P.

After the interlayer dielectric layer 138 is formed, a patterning process is performed to form gate-cut opening 140A through the dummy gate structure 112 using the photolithography and etching processes, in accordance with some embodiments. The trench pattern (CPO pattern) of the patterned mask layer is also transferred into the gate spacer layers 118, the contact etching stop layer 136 and the interlayer dielectric layer 138 by adjusting the etching selectivity of the anisotropic etching step between the dummy gate electrode layers 116 and these dielectric layers, in accordance with some embodiments. The portion of the trench pattern in the interlayer dielectric layer 138 is denoted as an opening 140B, as shown in FIG. 7A, in accordance with some embodiments.

The opening 140B extends between the source/drain features 134N and 134P and to the isolation structure 110, in accordance with some embodiments. In some embodiments, the gate-cut opening 140A are the opening 140B are connected. In some embodiments, the depth of the opening 140B is deeper than the gate-cut opening 140A. In some embodiments, the source/drain features 134N and 134P are not exposed from the opening 140B. In some other embodiments, the source/drain features 134N and 134P may be not exposed from the opening 140B. In the Y direction, the gate-cut opening 140A is wider than the opening 140B due the isotropic etching step described above in FIGS. 3H-1 to 3H-3, in accordance with some embodiments.

The steps described above in FIGS. 3I-1 through 3Q-3 are performed to form semiconductor features 142, the wall structure 144, the final gate stacks 170 and the gate-cut structure 172, as shown in FIGS. 7B and 7B-1, in accordance with some embodiments. A first portion of the wall structure 144 sandwiched between the gate segment 170A1 and the gate segment 170B1 is wider than a second portion of the wall structure 144 sandwiched between the source/drain feature 134N and the source/drain feature 134P, as shown in FIG. 7B-2, in accordance with some embodiments.

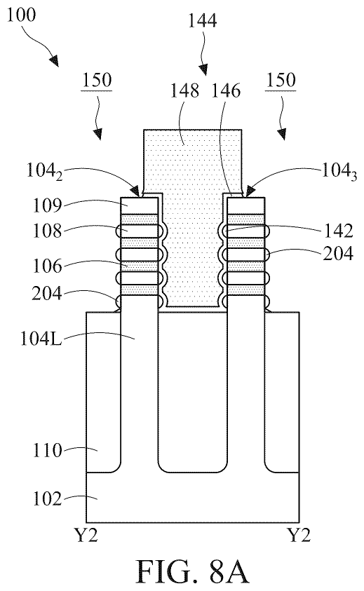

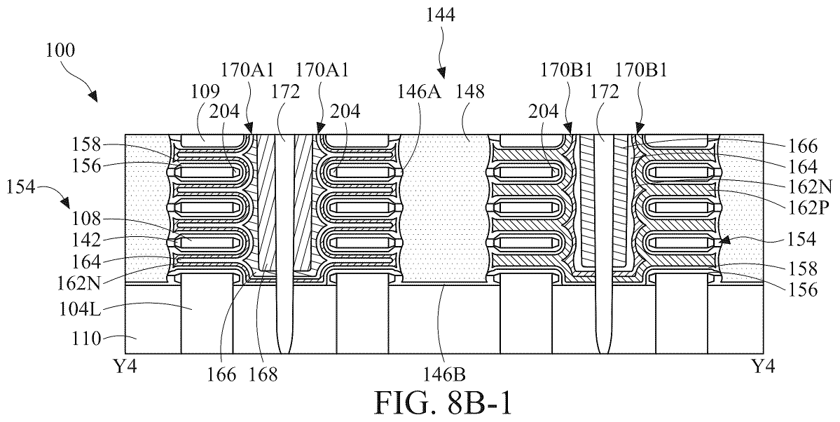

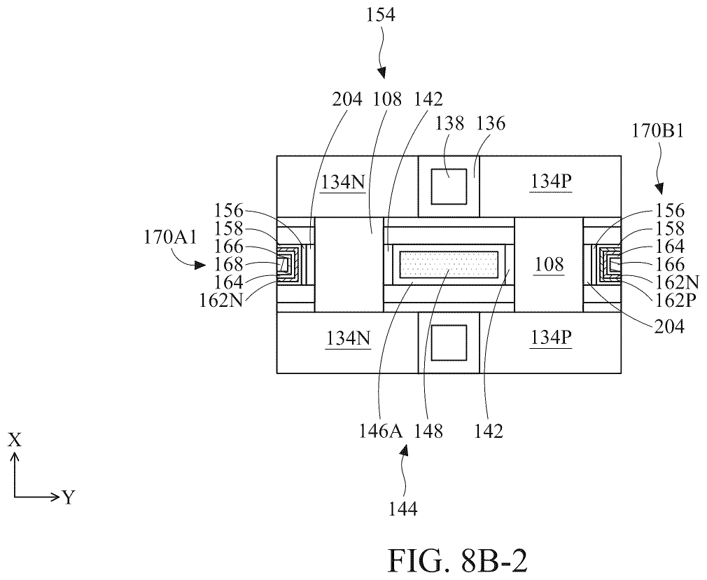

FIGS. 8A and 8B-1 are cross-sectional views illustrating the formation of the semiconductor structure 100 of FIG. 2 at various intermediate stages, in accordance with some embodiments of the disclosure. FIG. 8A corresponds to line Y2-Y2 of FIG. 2, and FIG. 8B-1 corresponds to line Y4-Y4 of FIG. 2. FIG. 8B-2 is a plan view corresponding to line A-A of FIG. 3Q-1. The embodiments of the FIGS. 8A and 8B-1 are similar to the embodiments of FIGS. 3A through 3Q-5 except that semiconductor features 204 are formed on the second semiconductor layers 208 and the lower fin elements 104L.

After the gate dielectric layer 114 of the dummy gate structures 112 are removed, semiconductor features 204 are selectively grown on the sidewalls of the second semiconductor layers 108 of the active regions 104 exposed from the gate trenches 150 using an epitaxial growth process, as shown in FIG. 8A, in accordance with some embodiments. The semiconductor features 204 are also grown on the exposed sidewalls of the top portions of the lower fin elements 104L, in accordance with some embodiments. The epitaxial growth process may be MBE, MOCVD, or VPE, another suitable technique, or a combination thereof.

In some embodiments, the semiconductor features 204 are made of the same material as the second semiconductor layers 108, and have the same composition as the second semiconductor layers 108. In an embodiment, the semiconductor features 204 and the second semiconductor layers 108 are made of pure or substantially pure silicon. In an embodiment, the semiconductor features 204 and the second semiconductor layers 108 are made of SiGe with the same Ge concentration. In some other embodiments, the semiconductor features 204 and the second semiconductor layers 108 have different compositions, for example, they are made of SiGe with different Ge concentrations.

The steps described above in FIGS. 3M-1 through 3Q-3 are performed to form the final gate stacks 170 and the gate-cut structure 172, as shown in FIGS. 8B and 8B-1, in accordance with some embodiments. The semiconductor features 204 are sandwiched between the gate spacer layers 118, in accordance with some embodiments. The formation of the semiconductor features 202 may further increase the effective channel width, which may increase the on-state current of the transistors, thereby boosting the performance of the resulting semiconductor device.

As described above, the semiconductor structure includes the gate stack 170 and the wall structure 144 penetrating through the gate stack 170. The wall structure 144 is formed self-aligned at the location of the dummy gate structure 112 between the active regions 104, and thus may cut the gate stack 170 in a manner that minimizes the end-cap dimension. Therefore, the total cell capacitance of the resulting semiconductor device may be reduced, and scaling down the resulting semiconductor device may be achieved.

In addition, the semiconductor structure further includes the semiconductor features 142 grown on the sidewalls of the second semiconductor layers 108 facing the wall structure 144. As a result, the effective channel width may increase without negatively affecting the filling of the final gate stacks 170. Therefore, the on-state current of the resulting semiconductor device may increase.

Embodiments of a semiconductor structure and the method for forming the same may be provided. The method for forming the semiconductor structure may include etching the dummy gate structure to form an opening exposing an active region, selectively forming semiconductor features on the second semiconductor layers of the active region, and forming a wall structure in the opening. As a result, the total cell capacitance of the resulting semiconductor device may be reduced, the on-state current of the resulting semiconductor device may increase, and scaling down the resulting semiconductor device may be achieved.

In some embodiments, a method for forming a semiconductor structure is provided. The method includes forming a first fin structure and a second fin structure. Each of the first fin structure and the second fin structure includes a stack of alternating first semiconductor layers and second semiconductor layers. The method also includes forming a dummy gate structure across the first fin structure and the second fin structure, partially etching the dummy gate structure to form an opening exposing the first fin structure and the second fin structure, selectively forming first semiconductor features on the second semiconductor layers of each of the first fin structure and the second fin structure, and forming a wall structure in the opening.

In some embodiments, a method for forming a semiconductor structure is provided. The method includes forming a stack of alternating first semiconductor layers and second semiconductor layers on a substrate, patterning the stack and a portion of the substrate to form an active region, and forming a dummy gate segment over the active region. An edge of the dummy gate segment terminates on a top surface of the active region. The method also includes growing semiconductor features on first sidewalls of the second semiconductor layers of the active region, forming a wall structure to abut the dummy gate segment and the active region, and removing the dummy gate segment and the first semiconductor layers of the active region.

In some embodiments, a semiconductor structure is provided. The semiconductor includes a first plurality of nanostructures between a first source/drain feature and a second source/drain feature, a first gate segment surrounding the first plurality of nanostructures, and a wall structure abutting the first gate segment. A first nanostructure in the first plurality of nanostructures includes a bulk portion and a protrusion, and in a plan view, the protrusion protrudes from a first sidewall of the bulk portion toward the wall structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first fin structure and a second fin structure on a semiconductor substrate, wherein each of the first fin structure and the second fin structure includes a stack of alternating first semiconductor layers and second semiconductor layers;
forming a dummy gate structure across the first fin structure and the second fin structure;
partially etching the dummy gate structure to form an opening to expose sidewalls of the first fin structure and the second fin structure in the opening;
selectively forming first semiconductor features on the second semiconductor layers of each of the first fin structure and the second fin structure through the opening; and
filling a dielectric wall structure in the opening, the dielectric wall structure contacting the first semiconductor features.

2. The method of claim 1, wherein
the wall structure includes a dielectric lining layer and a dielectric bulk layer on the dielectric lining layer; and
the dielectric lining layer and the dielectric bulk layer are different in composition.

3. The method of claim 2, further comprising:
removing the dummy gate structure;
removing first semiconductor layers of each of the first fin structure and the second fin structure; and
partially removing the dielectric lining layer to expose the dielectric bulk layer.

4. The method of claim 3, further comprising:
forming second semiconductor features on the second semiconductor layers after removing the dummy gate structure and before removing first semiconductor layers.

5. The method of claim 3, further comprising:
trimming the second semiconductor layers and the second semiconductor features.

6. The method of claim 1, wherein each of the first fin structure and the second fin structure includes a lower fin portion underlying the alternatingly stacked first semiconductor layers and second semiconductor layers, and the semiconductor features are further formed on a sidewall of the lower fin portion.

7. The method of claim 1, further comprising:
forming gate spacer layers on opposite sides of the dummy gate structure, wherein the gate spacer layers are exposed the opening.

8. The method of claim 7, wherein the first semiconductor features are located between the gate spacer layers.

9. The method of claim 1, wherein each of the first fin structure and the second fin structure includes a mask layer over the stack of the first semiconductor layers and the second semiconductor layers, and the method further includes:
removing the dummy gate structure and the first semiconductor layers; and
forming a gate stack to surround the second semiconductor layers and the mask layers.

10. A method, comprising:
forming a stack of alternating first semiconductor layers and second semiconductor layers on a substrate;
patterning the stack and a portion of the substrate to form an active region;
forming a dummy gate segment over the active region, first sidewalls of the second semiconductor layers of the active region are uncovered by the dummy gate segment;
growing semiconductor features on the first sidewalls of the second semiconductor layers of the active region;
forming a dielectric wall structure to abut the dummy gate segment and the active region, the dielectric wall structure contacting the semiconductor features;
removing the dummy gate segment and the first semiconductor layers of the active region; and
forming a gate stack to wrap around the second semiconductor layers.

11. The method of claim 10, wherein
the second semiconductor layers of the active region have second sidewalls opposite to the first sidewalls; and
the second sidewalls of the second semiconductor layers of the active region are covered by the dummy gate segment while growing the semiconductor features on the first sidewalls of the second semiconductor layers of the active region.

12. The method of claim 10, wherein
the dielectric wall structure includes a dielectric lining layer and a dielectric bulk layer on the dielectric lining layer; and
the dielectric lining layer and the dielectric bulk layer are different in composition and etching resistance.

13. The method of claim 12, further comprising:
etching the dielectric lining layer to form a plurality of dielectric features, wherein the dielectric features are in direct contact with the semiconductor features.

14. The method of claim 12, further comprising:
removing the dielectric lining layer, wherein the forming of the gate stack includes forming a gate dielectric layer to wrap around the second semiconductor layers and semiconductor features, wherein the gate dielectric layer includes a portion extending into a space between the semiconductor features and the dielectric bulk layer.

15. A semiconductor structure, comprising:
a first plurality of nanostructures between a first source/drain feature and a second source/drain feature;
semiconductor features are disposed on first sidewalls of the first plurality of nanostructures;
a first gate segment wrapping around the first plurality of nanostructures; and
a dielectric wall structure abutting the first gate segment and contacting the semiconductor features.

16. The semiconductor structure of claim 15, further comprising:
gate spacer layers on opposite sides of the first gate segment and on opposite sides of the dielectric wall structure, wherein
a first nanostructure in the first plurality of nanostructures includes a bulk portion and a protrusion, and in a plan view, the protrusion protrudes from a first sidewall of the bulk portion toward the dielectric wall structure; and
the protrusion of the first nanostructure is sandwiched between the gate spacer layers.

17. The semiconductor structure of claim 16, wherein:
the first gate segment includes a high-k dielectric layer, the high-k dielectric layer has a first portion extending over the first nanostructure, and the first portion of the high-k dielectric layer has a bottommost point that is lower than a top surface of the bulk layer of the first nanostructure, and
the high-k dielectric layer has a second portion extending under the first nanostructure, and the second portion of the high-k dielectric layer has a topmost point that is higher than a bottom surface of the bulk layer of the first nanostructure.

18. The semiconductor structure of claim 17, wherein the first gate segment includes a high-k dielectric layer, and the high-k dielectric layer includes a portion extending between the protrusion of the nanostructure and the wall structure.

19. The semiconductor structure of claim 15, further comprising:
a fin element under the nanostructures, wherein a first width of the nanostructure is greater than a second width of the fin element; and
an isolation structure surrounding the fin element.

20. The semiconductor structure of claim 15, further comprising:
a second plurality of nanostructures between a third source/drain feature and a fourth source/drain feature; and
a second gate stack surrounding the second plurality of nanostructures, wherein the wall structure includes a first portion sandwiched between the first gate segment and the second gate segment and a second portion sandwiched between the first source/drain feature and the third source/drain feature, and the first portion of the wall structure is wider than the second portion of the wall structure.
